(19) United States
(12) Patent Application Publication
(10) Pub. No.: US 2026/0129947 A1
(43) Pub. Date: May 7, 2026

(54) SEMICONDUCTOR DEVICE INCLUDING TRANSISTOR STRUCTURES AND WORK-FUNCTION FILM

(71) Applicant: Samsung Electronics Co., Ltd., Suwon-si (KR)

(72) Inventors: Byungho MOON, Suwon-si (KR); Minwoo KIM, Suwon-si (KR); Donghoon HWANG, Suwon-si (KR); Seongkwang KIM, Suwon-si (KR); Hyunsoo KIM, Suwon-si (KR); Wonchang LEE, Suwon-si (KR); Jaeho JEON, Suwon-si (KR)

(21) Appl. No.: 19/334,754

(22) Filed: Sep. 19, 2025

(30) Foreign Application Priority Data
Nov. 1, 2024 (KR) 10-2024-0153650

(51) Int. Cl. H10D 64/66; H10D 62/10; H10D 64/27; H10D 84/01; H10D 84/83

(52) U.S. Cl. CPC H10D 64/671; H10D 62/115; H10D 64/518; H10D 84/0135; H10D 84/0153; H10D 84/832; H10D 62/121

(57) ABSTRACT

A semiconductor device includes a substrate, a plurality of transistor structures disposed on the substrate and spaced apart from each other in a first direction parallel to a surface of the substrate, each of the plurality of transistor structures including a lower portion active pattern and an upper portion active pattern spaced apart from the lower portion active pattern in a second direction intersecting the first direction, a gate cut film disposed between two adjacent transistor structures of the plurality of transistor structures, for each lower portion active pattern, a first layer that surrounds a portion of the lower portion active pattern, and a second layer disposed on each first layer. Each of the plurality of transistor structures includes a first work-function film surrounding the first portion of the lower portion active pattern and a second work-function film that surrounds a portion of the upper portion active pattern.

### CROSS-REFERENCE TO RELATED APPLICATIONS

This application claims the benefit of Korean Patent Application No. 10-2024-0153650, filed on Nov. 1, 2024, in the Korean Intellectual Property Office, the disclosure of which is incorporated herein by reference in its entirety.

### BACKGROUND

### 1. Field of the Invention

Example embodiments relate to a semiconductor device.

### 2. Description of the Related Art

As technology for integrated circuits with high density devices and high performance, fin field-effect transistor (FinFET) and nano sheet field-effect transistors have been introduced. The FinFET includes a channel layer surrounded by gate structures on at least three sides, and has one or more vertical fin structures disposed to extend in a horizontal direction. With respect to the nano sheet field-effect transistor, gate-all-around (GAA) transistor or multi-bridge channel (MBC) transistor products are known, for example, and the nano sheet field-effect transistor includes one or more nano sheet channel layers vertically stacked on a substrate and a gate structure surrounding the all-around surface of each nano sheet channel layer.

Meanwhile, in order to increase the density of the devices, 3D stacked field-effect transistors (3DSFET) have been proposed, in which a lower nano sheet field-effect transistor and an upper nano sheet field-effect transistor are stacked. Recently, the size of standard cells included in integrated circuits has been decreasing due to downscaling of semiconductor devices, and for devices including cross-couple structures, generally, design rules must not be violated in order to implement a standard cell of reduced size.

### SUMMARY

An aspect provides a semiconductor device of which integration may be improved by downscaling, and electrical reliability may be improved.

The technical tasks to be achieved by the present example embodiments are not limited to the technical tasks described above or below, and other technical tasks may be inferred from the following example embodiments by those skilled in the art.

According to an aspect, a semiconductor device includes a substrate, a plurality of transistor structures disposed on the substrate and spaced apart from each other in a first direction parallel to a surface of the substrate, each of the plurality of transistor structures including a lower portion active pattern and an upper portion active pattern spaced apart from the lower portion active pattern in a second direction intersecting the first direction, a gate cut film disposed between two adjacent transistor structures of the plurality of transistor structures, for each lower portion active pattern, a first layer that surrounds at least a first portion of the lower portion active pattern, and a second layer disposed on each first layer. Each of the plurality of transistor structures includes a first work-function film surrounding the first portion of the lower portion active pattern and a second work-function film that surrounds at least a first portion of the upper portion active pattern and extends in the first direction, and the gate cut film penetrates through the second work-function film to form a gap between a first part of the second work-function film and a second part of the second work-function film.

According to an aspect, a semiconductor device includes a substrate, a plurality of transistor structures disposed on the substrate and spaced apart from each other in a first direction parallel to a surface of the substrate, each including a lower portion active pattern including a plurality of sheets spaced apart from each other in a second direction intersecting the first direction, an upper portion active pattern spaced apart from the lower portion active pattern in the second direction and including a plurality of sheets that are spaced apart from each other in the second direction and a separating insulating film disposed between the lower portion active pattern and the upper portion active pattern, a gate cut film disposed between adjacent transistor structures of the plurality of transistor structures, a first layer that surrounds at least a portion of each of the lower portion active pattern, and a second layer disposed on the first layer. The gate cut film penetrates a work-function film in the second direction to fill a gap in the work-function film.

According to an aspect, a semiconductor device includes a substrate, a plurality of transistor structures disposed on the substrate and spaced apart from each other in a first direction parallel to a surface of the substrate, each including a lower portion active pattern including a plurality of sheets spaced apart from each other in a second direction intersecting the first direction, an upper portion active pattern spaced apart from the lower portion active pattern in the second direction and including a plurality of sheets spaced apart from each other in the second direction, and a separating insulating film disposed between the lower portion active pattern and the upper portion active pattern, a gate cut film disposed between adjacent transistor structures of the plurality of transistor structures, a first layer that surrounds at least a portion of each of the lower portion active pattern, and a second layer disposed on the first layer. The gate cut film penetrates a second work-function film in the second direction in order for the second work-function film to have a gap therein with respect to the first direction, and a length of the gate cut film with respect to the first direction decreases as the gate cut film gets closer to the substrate, the gate cut film includes a bottommost surface that is closer to the substrate than an uppermost surface of the separating insulating film is to the substrate, a portion of a first work-function film has a gap formed therein between the plurality of transistor structures, and the separating insulating film contacts the second work-function film.

Additional aspects of example embodiments will be set forth in part in the description which follows and, in part, will be apparent from the description, or may be learned by practice of the disclosure.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a layout drawing of a semiconductor device according to an example embodiment;

FIG. 2 is a drawing illustrating a cross-section taken along line I-I′ of FIG. 1, according to an example embodiment;

FIG. 3 is an enlarged view of a portion P of FIG. 2;

FIG. 4 is another drawing illustrating a cross-section taken along line I-I′ of FIG. 1, according to an example embodiment;

FIG. 5 is an enlarged view of a portion Q of FIG. 4;

FIG. 6 is an enlarged view of a portion R of FIG. 4;

FIG. 7 is a drawing illustrating a first transistor structure that is to include a common gate structure with the dummy gate structure surrounding the active patterns removed and a second transistor structure that is to include a split gate structure, according to an example embodiment;

FIG. 8 is a drawing illustrating a sacrificial film formed between the upper portion active patterns, according to an example embodiment;

FIG. 9 is a drawing illustrating the formation of a gate dielectric film, according to an example embodiment;

FIG. 10 is a drawing illustrating a sacrificial film formed between the upper portion active patterns, according to an example embodiment;

FIG. 11 is a drawing illustrating the state in which the first work-function film is formed, according to an example embodiment;

FIG. 12 is a drawing for explaining a method for manufacturing a semiconductor device according to a first example embodiment, and illustrates the state when a mask is formed, leaving a portion between the first transistor structure and the second transistor structure, and before cutting a portion of the first work-function film;

FIG. 13 is a drawing for explaining a method for manufacturing a semiconductor device according to the first example embodiment, and illustrates a state in which a portion of a first work-function film disposed between a first transistor structure and a second transistor structure is cut to form a recess and a first layer including an insulating material is deposited;

FIG. 14 is a drawing for explaining a method for manufacturing a semiconductor device according to the first example embodiment, and illustrates the state in which a polymer layer is formed after removing the first layer formed on the second transistor structure;

FIG. 15 is a drawing for explaining a method for manufacturing a semiconductor device according to the first example embodiment, and illustrates the state in which a portion of the first work-function film formed on the second transistor structure is removed;

FIG. 16 is a drawing for explaining a method for manufacturing a semiconductor device according to the first example embodiment, and illustrates the state of the first layer formed on the first transistor structure is removed after removing the polymer layer;

FIG. 17 is a drawing for explaining a method for manufacturing a semiconductor device according to the first example embodiment, and illustrates the state in which a first layer including an insulating material is re-deposited;

FIG. 18 is a drawing for explaining a method for manufacturing a semiconductor device according to the first example embodiment, and illustrates the state in which, after forming a polymer layer, a portion of the first layer formed on the first transistor structure and the second transistor structure is removed;

FIG. 19 is a drawing for explaining a method for manufacturing a semiconductor device according to the first example embodiment, and illustrates the state in which, after removing the polymer layer, a second layer including an insulating material is deposited;

FIG. 20 is a drawing for explaining a method for manufacturing a semiconductor device according to the first example embodiment, and illustrates a state in which a portion of the second layer formed on the first transistor structure and the second transistor structure is removed, and a portion of the first work-function film formed on the first transistor structure is removed;

FIG. 21 is a drawing for explaining a method for manufacturing a semiconductor device according to the first example embodiment, and illustrates the state in which a portion of the second layer is removed so that the first work-function film in the first transistor structure is exposed from the second layer;

FIG. 22 is a drawing for explaining a method for manufacturing a semiconductor device according to the first example embodiment, and illustrates the state after removing the sacrificial film that is formed between the upper portion active patterns;

FIG. 23 is a drawing for explaining a method for manufacturing a semiconductor device according to the first example embodiment, and illustrates the state in which a second work-function film is formed;

FIG. 24 is a drawing for explaining a method for manufacturing a semiconductor device according to the first example embodiment, and illustrates a cut recess formed by removing a portion of a second work-function film positioned between a first transistor structure and a second transistor structure;

FIG. 25 is a drawing for explaining a method for manufacturing a semiconductor device according to the first example embodiment, and illustrates the state that a gate cut film is formed by filling the formed cut recess;

FIG. 26 is a drawing for explaining a method for manufacturing a semiconductor device according to a second example embodiment, and illustrates the state in which a layer 1′ including an insulating material is deposited;

FIG. 27 is a drawing for explaining a method for manufacturing a semiconductor device according to the second example embodiment, and illustrates the state that a polymer layer is formed after removing the layer 1′ formed in the second transistor structure;

FIG. 28 is a drawing for explaining a method for manufacturing a semiconductor device according to the second example embodiment, and illustrates the state in which a portion of the first work-function film formed on the second transistor structure is removed;

FIG. 29 is a drawing for explaining a method for manufacturing a semiconductor device according to the second example embodiment, and illustrates the state in which, after removing the polymer layer, the layer 1′ formed in the first transistor structure is removed;

FIG. 30 is a drawing for explaining a method for manufacturing a semiconductor device according to the second example embodiment, and illustrates the state in which a first layer including a conductive material is re-deposited;

FIG. 31 is a drawing for explaining a method for manufacturing a semiconductor device according to the second example embodiment, and illustrates the state in which a mask is formed, leaving a portion between the first transistor structure and the second transistor structure, before cutting a portion of the first work-function film and a portion of a first layer;

FIG. 32 is a drawing for explaining a method for manufacturing a semiconductor device according to the second example embodiment, and illustrates the state in which a recess is formed by cutting a portion of the first work-function film disposed between the first transistor structure and the second transistor structure, and a polymer layer is formed;

FIG. 33 is a drawing for explaining a method for manufacturing a semiconductor device according to the second example embodiment, and illustrates the state in which a portion of the first layer formed in the first transistor structure and the second transistor structure is removed;

FIG. 34 is a drawing for explaining a method for manufacturing a semiconductor device according to the second example embodiment, and illustrates the state in which a second layer including an insulating material is deposited after removing the polymer layer;

FIG. 35 is a drawing for explaining a method for manufacturing a semiconductor device according to the second example embodiment, and illustrates the state in which a mask is formed while leaving the first transistor structure region, a portion of the second layer is removed so that the first layer is exposed from the second layer in the first transistor structure, and a portion of the first work-function film is removed;

FIG. 36 is a drawing for explaining a method for manufacturing a semiconductor device according to the second example embodiment, and illustrates the state in which a portion of the second layer formed on the second transistor structure is removed after the mask is removed;

FIG. 37 is a drawing for explaining a method for manufacturing a semiconductor device according to the second example embodiment, and illustrates the state after removing the sacrificial film formed between the upper portion active patterns;

FIG. 38 is a drawing for explaining a method for manufacturing a semiconductor device according to the second example embodiment, and illustrates the state in which a second work-function film is formed;

FIG. 39 is a drawing for explaining a method for manufacturing a semiconductor device according to the second example embodiment, and illustrates a cut recess formed by removing a portion of a second work-function film positioned between a first transistor structure and a second transistor structure; and

FIG. 40 is a drawing for explaining a method for manufacturing a semiconductor device according to the second example embodiment, and illustrates the state in which a gate cut film is formed by filling the formed cut recess.

### DETAILED DESCRIPTION

The drawings illustrated in the present disclosure are according to mere example embodiments, and the ratio of the width, the length and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the − direction. Unless specifically designated, the description of an item as extending in a direction (e.g., in a first direction, second direction, horizontal direction, or vertical direction) is intended to cover both the + and − direction. To designate the + or − direction, either the + or − symbols will be used, or terms such as a positive direction or negative direction will be used.

The same reference numeral or sign shown in each drawing attached to the specification may represent parts or components that perform substantially the same function. For convenience of description and understanding, different embodiments may be described using the same reference numerals or symbols. For example, even if a component or an element having the same reference numeral is shown in multiple drawings, the multiple drawings may not all represent one example embodiment.

It will be understood that when an element is referred to as being “connected” or “coupled” to, “adjacent to” or “on” another element, it can be directly connected, coupled to, adjacent to, or on the other element or intervening elements may be present. In contrast, when an element is referred to as being “directly connected” or “directly coupled” to another element, as “directly adjacent to” or as “contacting” or “in contact with” another element (or using any form of the word “contact”), there are no intervening elements present at the point of connection, coupling, contact, or adjacency.

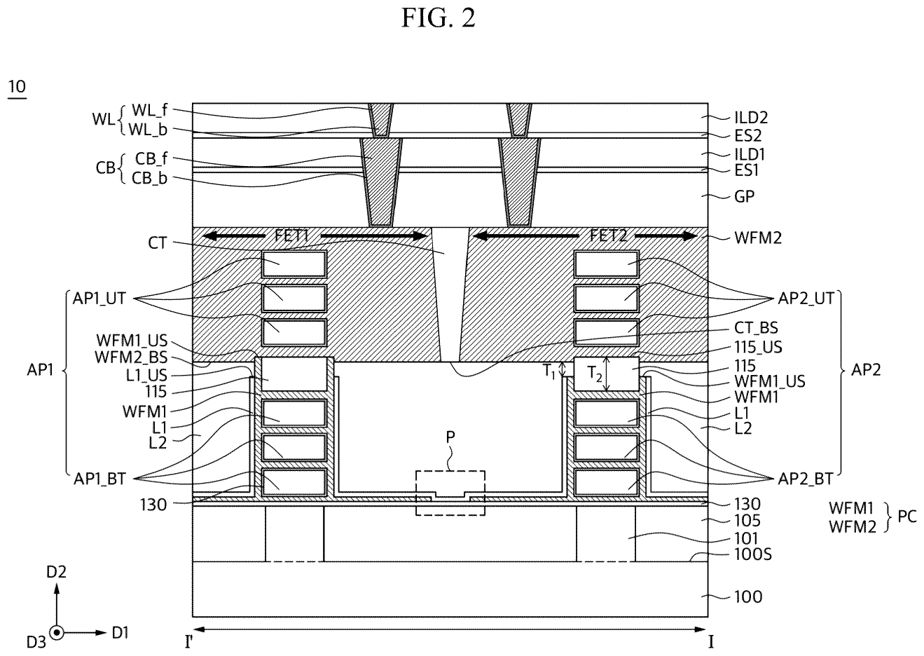

Further, in the present disclosure, when an element is described as being “on an upper surface” or “on an upper portion” of another element, it may be understood as existing above the vertical direction, for example, as being above the +D2 direction in the drawing (FIG. 2), and the two elements may be in contact or directly connected, but it may also be understood that another element exists between the two. The same is applied even when an element is described as being “above/over” another element in the present disclosure.

Further, in the present disclosure, when an element is described as being “on a lower portion” or “on a bottom surface” of another element, it may be understood as existing below based on the vertical direction, for example, being further below based on the −D2 direction in the drawing (FIG. 2), and the two elements may be in contact or directly connected, but it may also be understood that another element exists between the two. The same is applied even when an element is described as being “underneath/beneath” another element.

Other similar expressions describing the positional relationship between elements can also be interpreted similarly as above.

Items described in the singular herein may be provided in plural, as can be seen, for example, in the drawings. Thus, the description of a single item that is provided in plural should be understood to be applicable to the remaining plurality of items unless context indicates otherwise. The terms “have,” “may have,” “include,” and “may include” as used herein indicate the presence of corresponding features (for example, elements such as numerical values, functions, operations, or parts), and do not preclude the presence of additional features. Also, throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Further, in the following description, expressions such as upper side, upper surface, lower side, lower surface, side, a front side and a back side are expressed based on the direction shown in the drawing. If the direction of the object changes, it may be expressed differently.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

The properties described in the present disclosure may have units according to the international system of units unless otherwise specified.

Drawings of a semiconductor device according to an example embodiment illustrate a FinFET or nano sheet field-effect transistor, but the present disclosure is not limited thereto. In an example embodiment, the semiconductor device may include one or more of a tunneling FET, a 3D transistor and a vertical FET. In an example embodiment, the semiconductor device may include a planar transistor. Further, in example embodiments, the semiconductor device may be applied to 2D material based transistors (2D material based FETs) and their heterostructures. In an example embodiment, the semiconductor device may include at least one of a bipolar junction transistor and a lateral double diffused FET.

Further, hereinafter, example embodiments according to the technical idea of the present invention will be described with reference to the attached drawings. Further, for brevity, existing elements, structures or layers of a semiconductor device according to an example embodiment may be described in detail herein, or may not be described. For example, the description of one or more source/drain regions, contact structures, isolation structures of a field-effect transistor included in a semiconductor device, other structure and/or substances forming the same may be omitted when they are not relevant to the novel features of example embodiments.

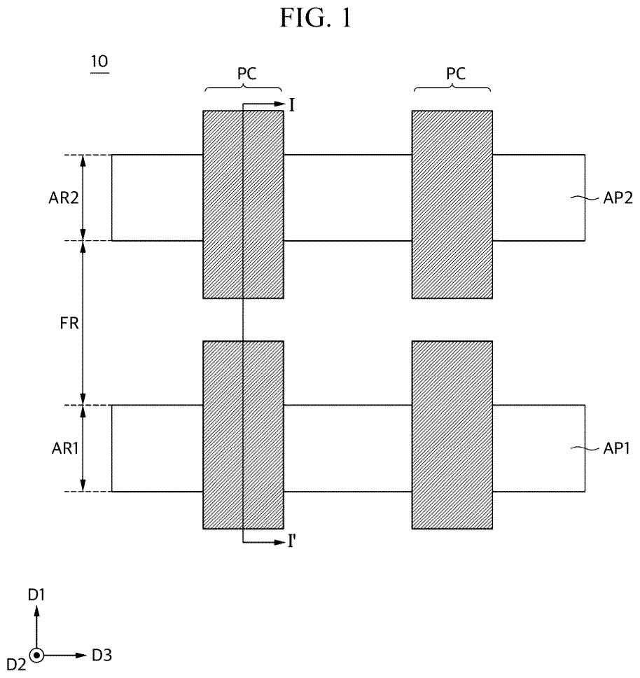

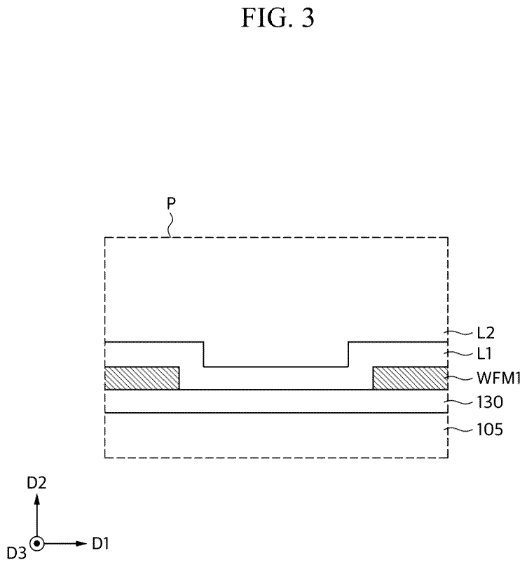

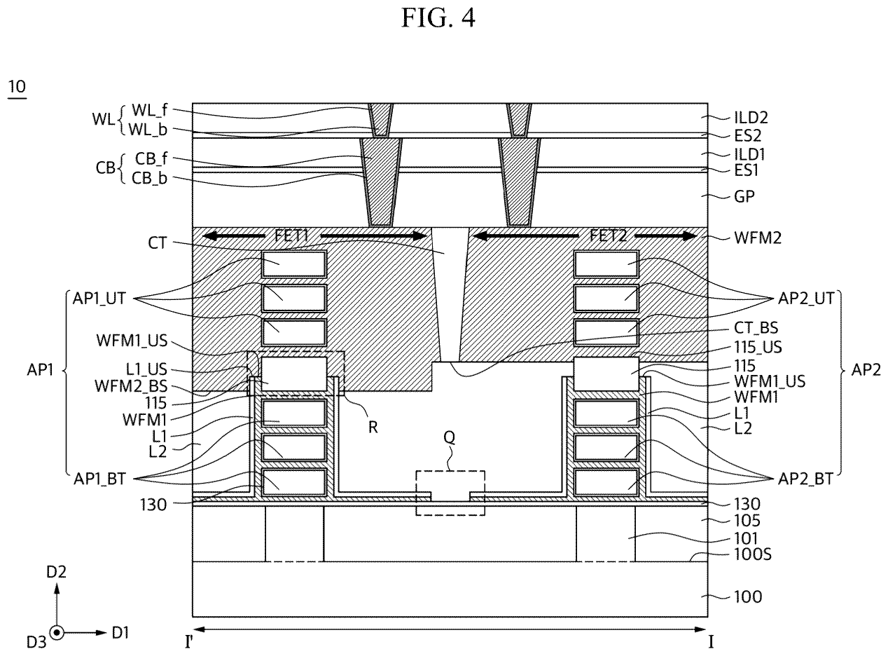

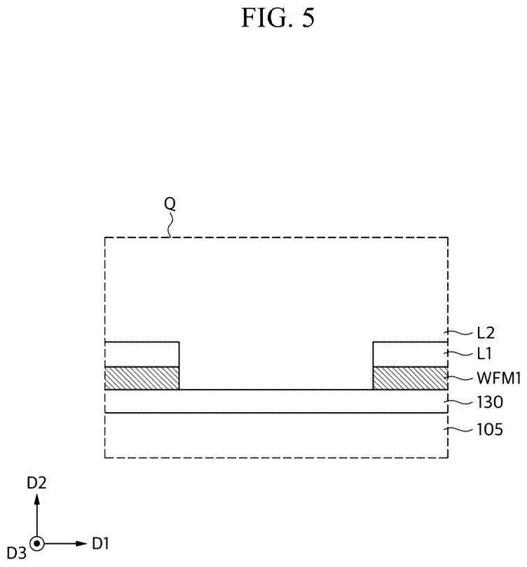

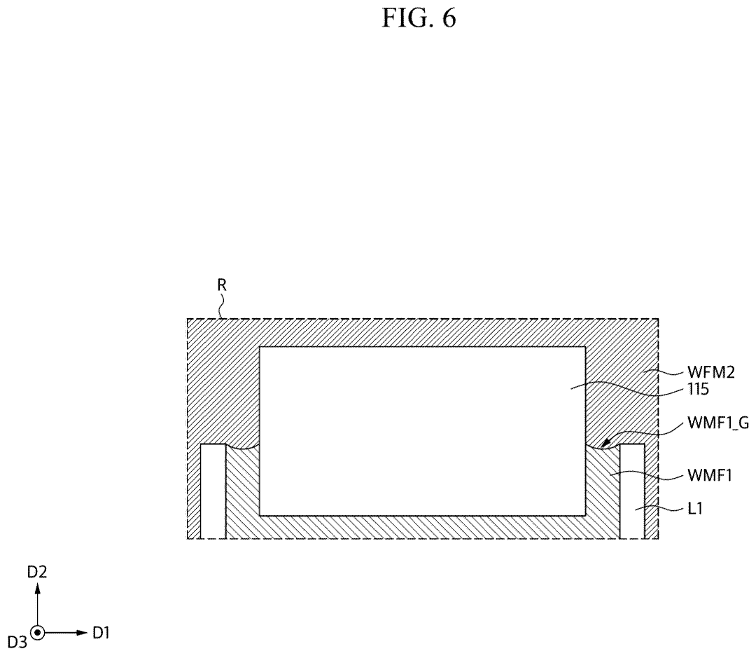

FIG. 1 is an exemplary layout drawing of a semiconductor device 10 according to one example embodiment of the present disclosure. The items shown in FIG. 1 are part of the semiconductor device 10, which may be a semiconductor chip or die formed from a wafer and including an integrated circuit formed thereon. FIG. 2 is a drawing illustrating a cross-section taken along line I-I′ of FIG. 1 showing one embodiment. FIG. 3 is an enlarged view of a portion P of FIG. 2. FIG. 4 is another drawing illustrating a cross-section taken along line I-I′ of FIG. 1 showing a different embodiment or a different section of the semiconductor device 10 having a different structure from the example in FIG. 2. FIG. 5 is an enlarged view of a portion Q of FIG. 4. FIG. 6 is an enlarged view of a portion R of FIG. 4.

In the present disclosure, the first direction D1 may be a direction parallel to a surface 100S of the substrate. The second direction D2 may be a direction intersecting the first direction D1. The second direction D2 may be a direction perpendicular to the surface 100S of the substrate. The third direction D3 may be a direction intersecting the first direction D1 and the second direction D2. The third direction D3 may be a direction parallel to the surface 100S of the substrate. In an example embodiment, the first direction D1 and the second direction D2 may be perpendicular, and the second direction D2 and the third direction D3 may be perpendicular, and the first direction D1 and the third direction D3 may be perpendicular.

In an example embodiment, the semiconductor device 10 may include a substrate 100, a plurality of transistor structures (a first transistor structure FET1 and a second transistor structure FET2), a gate cut film CT, a first layer L1 and a second layer L2. Each transistor structure FET1 and FET2 may be a 3D stacked field-effect-transistor, including for example, two transistors stacked vertically on each other. The circuit in FIGS. 2-4 may be, for example, a set of cross-coupled transistors.

In an example embodiment, the substrate 100 may be bulk silicon or silicon-on-insulator (SOI). Alternatively, the substrate 100 may be a silicon substrate, or the substrate 100 may include other materials, for example, silicon germanium, silicon germanium on insulator (SGOI), indium antimonide, lead telluride, indium arsenide, indium phosphide, gallium arsenide or gallium antimonide. However, the substrate 100 is not limited thereto. As the substrate 100 may include at least one semiconductor layer in some embodiments, it may be a semiconductor substrate.

In an example embodiment, the semiconductor device 10 may include a first active region AR1, a second active region AR2, and a field region FR. In an example embodiment, each of the first active region AR1 and the second active region AR2 may extend in the third direction D3, to extend lengthwise in the third direction D3. An item, layer, or portion of an item or layer described as extending “lengthwise” in a particular direction or extending “along” a particular direction has a length in the particular direction and a width perpendicular to that direction, where the length is greater than the width. The first active region AR1 and the second active region AR2 may be spaced apart from each other in the first direction D1. In an example embodiment, the field region FR is disposed between the first active region AR1 and the second active region AR2, so as to separate the first active region AR1 and the second active region AR2. The field region FR may form a boundary with the first active region AR1 and the second active region AR2.

In an example embodiment, the field region FR may be defined by an existing trench, but is not limited thereto. In an example embodiment, the field region FR may have a shallow trench isolation (STI) structure, but the field region FR is not limited thereto.

In an example embodiment, a device-separating film STI (not illustrated) may be disposed around the first active region AR1 and the second active region AR2, which are spaced apart from each other. The region between the first active region AR1 and the second active region AR2 in the device-separating film STI may be the field region FR. In an example embodiment, in the semiconductor device 10, a region where a first active pattern AP1 is formed may be the first active region AR1, and a region where a second active pattern AP2 is formed may be the second active region AR2. The region that separates the first active pattern AP1 and the second active pattern AP2 may be the field region FR. The first active pattern AP1 and the second active pattern AP2 may include a fin structure or a nano sheet, and the field region FR may be a region that does not include fin structures or nano sheets.

In an example embodiment, the first active pattern AP1 may include a first lower portion active pattern AP1_BT and a first upper portion active pattern AP1_UT spaced apart from the first lower portion active pattern AP1_BT in the second direction D2. In an example embodiment, the second active pattern AP2 may include a second lower portion active pattern AP2_BT and a second upper portion active pattern AP2_UT spaced apart from the second lower portion active pattern AP2_BT in the second direction D2. In the present disclosure, the first lower portion active pattern AP1_BT and the second lower portion active pattern AP2_BT may be a lower portion active pattern, and the first upper portion active pattern AP1_UT and the second upper portion active pattern AP2_UT may be an upper portion active pattern.

In an example embodiment, each of the lower portion active pattern (e.g., the first lower portion active pattern AP1_BT and the second lower portion active pattern AP2_BT) and the upper portion active pattern (e.g., the first upper portion active pattern AP1_UT and the second upper portion active pattern AP2_UT) may independently include one or more sheets. In an example embodiment, each of the lower portion active pattern (e.g., the first lower portion active pattern AP1_BT and the second lower portion active pattern AP2_BT) and the upper portion active pattern (e.g., the first upper portion active pattern AP1_UT and the second upper portion active pattern AP2_UT) may include a plurality of sheets. Here, the plurality of sheets may be spaced apart from each other, and for example, the plurality of sheets may be spaced apart from each other in the second direction D2. Further, the sheets may extend, e.g., lengthwise, in the third direction D3. The drawings illustrate that each of the lower portion active pattern (e.g., the first lower portion active pattern AP1_BT and the second lower portion active pattern AP2_BT) and the upper portion active pattern (e.g., the first upper portion active pattern AP1_UT and the second upper portion active pattern AP2_UT) includes three sheets, but the illustration is for convenience of explanation only and the present disclosure is not limited thereto.

In an example embodiment, each of the lower portion active pattern (e.g., the first lower portion active pattern AP1_BT and the second lower portion active pattern AP2_BT) and the upper portion active pattern (e.g., the first upper portion active pattern AP1_UT and the second upper portion active pattern AP2_UT) may independently include either a p-channel metal-oxide semiconductor (PMOS) or an n-channel metal-oxide semiconductor (NMOS). For example, the lower portion active pattern (the first lower portion active pattern AP1_BT and the second lower portion active pattern AP2_BT) may include the PMOS, and the upper portion active pattern (the first upper portion active pattern AP1_UT and the second upper portion active pattern AP2_UT) may include the NMOS. For example, the sheets that form the first lower portion active pattern AP1_BT may be active regions of a first PMOS transistor, the sheets that form the first upper portion active pattern AP1_UT may be active regions of a first NMOS transistor, the sheets that form the second lower portion active pattern AP2_BT may be active regions of a second PMOS transistor, and the sheets that form the second upper portion active pattern AP2_UT may be active regions of a second NMOS transistor. The four transistors shown for example in FIG. 2 may be connected in a cross-coupled manner (not fully shown). However, the types of transistors and manner of connection is not limited to these examples.

In an example embodiment, each of the lower portion active pattern (the first lower portion active pattern AP1_BT and the second lower portion active pattern AP2_BT) and the upper portion active pattern (the first upper portion active pattern AP1_UT and the second upper portion active pattern AP2_UT) may independently include at least one of silicon (Si) and germanium (Ge). In another example embodiment, each of the lower portion active pattern (the first lower portion active pattern AP1_BT and the second lower portion active pattern AP2_BT) and the upper portion active pattern (the first upper portion active pattern AP1_UT and the second upper portion active pattern AP2_UT) may independently include a compound semiconductor. In the present disclosure, the compound semiconductor may include, for example, a group IV-IV compound semiconductor or a group III-V compound semiconductor. More specifically, the compound semiconductor may include a binary compound, or a ternary compound including a group IV element of at least two of carbon (C), silicon (Si), germanium (Ge) and tin (Sn). In an example embodiment, for example, the III-V compound semiconductor may be a binary compound, a ternary compound, or a quaternary compound formed by combining at least one of aluminum (Al), gallium (Ga), and indium (In), which are group III elements, with at least one of phosphorus (P), arsenic (As) and antimony (Sb), which are group V elements.

In an example embodiment, the semiconductor device 10 may include a plurality of gate lines PC, each disposed to extend along the first direction D1. Each gate line PC may be electrically connected to the first active pattern AP1 and the second active pattern AP2. At least some of the gate lines PC may be cut with respect to the first direction D1, which is the extending direction. The region of the gate line PC that is cut off may overlap with the field region FR when viewed from the second direction D2. When a gate line PC is cut off, it may comprise two gate line portions, which may each be independently considered to be a gate line.

In an example embodiment, the semiconductor device 10 may include a plurality of gate lines PC. In an example embodiment, there may be three gate lines PC or less, or 2 or less, and preferably, there may be two gate lines PC in a standard cell unit. The plurality of gate lines PC may be spaced apart from each other in the third direction D3. In an example embodiment, the gate line PC may include a first work-function film WFM1 and a second work-function film WFM2.

In an example embodiment, the gate line PC may include a conductive material. In the present disclosure, the conductive material may have an electrical conductivity greater than 10⁶ S/m. For example, the conductive material may include at least one of a metal, a metal alloy, a conductive metal nitride, a metal silicide, a doped semiconductor material, a conductive metal oxide, and a conductive metal oxynitride. For example, the conductive material may include at least one selected from the group consisting of titanium nitride (TiN), tantalum carbide (TaC), tantalum nitride (TaN), titanium silicon nitride (TiSiN), and tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and vanadium (V). However, the present disclosure is not limited thereto. The conductive metal oxide and conductive metal oxynitride may include an oxidized form of the above-described substances, but the present disclosure is not limited thereto.

In an example embodiment, the gate line PC may include not only the first work-function film WFM1 and the second work-function film WFM2, but also a gate dielectric film 130 and a gate capping film GP. The conductive portions of each gate line PC or gate line portion may be gate electrodes, which transmit signals or power.

In an example embodiment, some of the gate line portions of the gate lines PC including the cut region may be electrically connected to the first active pattern AP1, and others may be electrically connected to the second active pattern AP2. In an example embodiment, the gate line PC may surround the first active pattern AP1. Further, the gate line PC may surround the second active pattern AP2.

In an example embodiment, the semiconductor device 10 may include a plurality of transistor structures (the first transistor structure FET1 and the second transistor structure FET2) disposed on the substrate 100. Each transistor structure may be a transistor stack (e.g., a stack of transistors stacked vertically on each other). That is, the plurality of transistor structures may be transistor stacks. The plurality of transistor structures (the first transistor structure FET1 and the second transistor structure FET2) may be disposed spaced apart from each other in the first direction D1. Each of the plurality of transistor structures (the first transistor structure FET1 and the second transistor structure FET2) may include a lower portion active pattern (the first lower portion active pattern AP1_BT or the second lower portion active pattern AP2_BT, each which forms an active pattern of a respective transistor) and an upper portion active pattern (the first upper portion active pattern AP1_UT or the second upper portion active pattern AP2_UT, each which forms an active pattern of a respective transistor).

In an example embodiment, the semiconductor device 10 may include a fin type pattern 101 provided with and disposed on the substrate 100. The fin type pattern 101 may be formed in each of the first active region AR1 and the second active region AR2. The fin type pattern 101 may protrude from the substrate 100 and extend lengthwise in the third direction D3. For example, as a portion of the substrate 100, the fin type pattern 101 may be formed by etching a portion of the substrate 100. Further, the fin type pattern 101 may include an epitaxial layer grown from the substrate 100, for example. The fin type pattern 101 may include two or more elemental semiconductor materials such as silicon and germanium. In another example embodiment, the fin type pattern 101 may include a compound semiconductor. The fin type pattern 101 may be a fin, or may be a fin-shaped pattern.

In an example embodiment, disposed on each fin type pattern 101 may be a lower portion active pattern (e.g., the first lower portion active pattern AP1_BT or the second lower portion active pattern AP2_BT) and the upper portion active pattern (e.g., the first upper portion active pattern AP1_UT or the second upper portion active pattern AP2_UT) included in the plurality of transistor structures (the first transistor structure FET1 and the second transistor structure FET2).

In an example embodiment, the semiconductor device 10 may include a field insulating film 105 disposed in the field region FR. The field insulating film 105 may be disposed on the substrate 100. For example, the field insulating film 105 may be disposed on a region of the substrate 100 that does not overlap the first active pattern AP1 and the second active pattern AP2 when viewed from the second direction D2. In an example embodiment, the field insulating film 105 may cover the side wall of the fin type pattern 101. The field insulating film 105 may be disposed in order for the upper surface to be substantially at the same level as the upper surface of the fin type pattern 101 with respect to the second direction D2. Unlike what is illustrated, in another example embodiment, the field insulating film 105 may cover only a portion of the side wall of the fin type pattern 101. In this case, the portion of the side wall of the fin type pattern 101 may protrude further in the second direction D2 than the field insulating film 105. In an example embodiment, the field insulating film 105 may be a single film, and in another example embodiment, the field insulating film 105 may be multiple films.

In an example embodiment, the field insulating film 105 may include an insulating material. In the present disclosure, the insulating material may have an electrical conductivity of 10⁻⁶ S/m or less. In the present disclosure, the electrical conductivity is not specifically limited, but may be measured by ASTM E 1004, for example. In an example embodiment, the insulating material may include at least one selected from the group consisting of silicon oxide, silicon-germanium oxide, germanium oxide, silicon oxynitride, silicon nitride, a high-k material having a dielectric constant greater than that of silicon oxide, and a low-k material having a dielectric constant lower than that of silicon oxide. For example, the high-k material may include one or more of the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. However, the high-k material is not limited thereto. For example, the low-k material may include one or more of the group consisting of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels and mesoporous silica. However, the low-k material is not limited thereto.

In an example embodiment, the gate dielectric film 130 may be disposed to extend along the upper surface of the field insulating film 105 and the upper surface of the fin type pattern 101. The gate dielectric film 130 may wrap (e.g., surround, from a cross-sectional view) the first active pattern AP1 and the second active pattern AP2. The gate dielectric film 130 may be disposed along the perimeter of the sheets included in the first active pattern AP1 and the second active pattern AP2. The gate dielectric film 130 may include an insulating material, and may include at least one selected from the group consisting of silicon oxide, silicon-germanium oxide, germanium oxide, silicon oxynitride, silicon nitride and high-k material, for example. In an example embodiment, the gate dielectric film 130 may be a single film or, in another example embodiment, the gate dielectric film 130 may be multiple films.

In an example embodiment, a portion of the gate dielectric film 130 may be disposed between sheets included in the first active pattern AP1, between sheets included in the second active pattern AP2, between the first active pattern AP1 and the fin type pattern 101, and between the second active pattern AP2 and the fin type pattern 101.

In an example embodiment, the gate cut film CT may be disposed between a plurality of transistor structures (e.g., between two transistor structures such as the first transistor structure FET1 and the second transistor structure FET2). For example, the gate cut film CT may be disposed between the first transistor structure FET1 and the second transistor structure FET2. In an example embodiment, the gate cut film CT may have a length in the first direction D1 that gradually decreases as the gate cut film CT approaches the substrate 100. The gate cut film CT may include an insulating material. The gate cut film CT may only be disposed directly between (e.g., to be at the same vertical level as) the first upper portion active pattern AP1_UT and the second upper portion active pattern AP2_UT, and may not be directly between the first lower portion active pattern AP1_BT and the second lower portion active pattern AP2_BT.

In an example embodiment, each of the plurality of transistor structures (the first transistor structure FET1 and the second transistor structure FET2) may include the first work-function film WFM1 surrounding at least a portion of the lower portion active pattern (the first lower portion active pattern AP1_BT and the second lower portion active pattern AP2_BT). Each of the plurality of transistor structures (the first transistor structure FET1 and the second transistor structure FET2) may include the second work-function film WFM2 surrounding at least a portion of the upper portion active pattern (the first upper portion active pattern AP1_UT and the second upper portion active pattern AP2_UT). The second work-function film WFM2 may extend lengthwise in the first direction D1.

In an example embodiment, each of the first work-function film WFM1 and the second work-function film WFM2 may independently include a work function metal including at least one selected from the group consisting of titanium (Ti), aluminum (Al), tantalum (Ta), tungsten (W), molybdenum (Mo), copper (Cu), cobalt (Co), palladium (Pd), and platinum (Pt). Therefore, the first work-function film WFM1 and the second work-function film WFM2 may be formed of the same material as each other, or may be formed of different materials from each other, among the above materials. The first work-function film WFM1 and the second work-function film WFM2 may include at least one of a nitride of the work-function metal and a carbide of the work-function metal.

In an example embodiment, each of the first work-function film WFM1 and the second work-function film WFM2 may be composed of the NMOS or the PMOS. For example, the first work-function film WFM1 may form part of the PMOS portion of the semiconductor device 10, and the second work-function film WFM2 may form part of the NMOS portion of the semiconductor device 10. Further, in an alternate embodiment for example, the first work-function film WFM1 may form part of the NMOS portion of the semiconductor device 10, and the second work-function film WFM2 may form part of the PMOS portion of the semiconductor device 10. In an example embodiment, the first work-function film WFM1 and the second work-function film WFM2 may be a single film, such as depicted in the drawing, though in other embodiments, the first work-function film WFM1 and the second work-function film WFM2 may be multiple films.

In an example embodiment, a portion of the first work-function film WFM1 may be cut between the plurality of transistor structures (the first transistor structure FET1 and the second transistor structure FET2). For example, the first work-function film WFM1, which is disposed between the first transistor structure FET1 and the second transistor structure FET2, may be cut along the second direction D2, so that in the first direction D1, a gap is formed in the first work-function film WFM1 between a portion connected to the first transistor structure FET1 and a portion connected to the second transistor FET2. By cutting the first work-function film WFM1, which acts as a lower portion gate, along the second direction D2, the semiconductor device 10 may have a structure in which the lower portion gate between the first transistor structure FET1 and the second transistor structure FET2 is isolated.

In an example embodiment, the first layer L1 may surround at least a portion of the lower portion active pattern (the first lower portion active pattern AP1_BT and the second lower portion active pattern AP2_BT). For example, the first layer L1 may surround at least a portion of each of the first lower portion active pattern AP1_BT and the second lower portion active pattern AP2_BT.

In an example embodiment, at least a portion of the first layer L1 may be disposed on the first work-function film WFM1. The first layer L1 may contact the first work-function film WFM1. The first layer L1 may be spaced apart from the second work-function film WFM2 in the second direction D2.

In an example embodiment, the second layer L2 may be disposed on the first layer L1. The second layer L2 may include an insulating material. For example, the second layer L2 may include silicon nitride.

In an example embodiment, the second layer L2 may be in contact with a portion of the second work-function film WFM2. The second layer L2 may contact a portion of the first work-function film WFM1. The second layer L2 may contact a bottom surface CT_BS of the gate cut film. The second layer L2 may be disposed to extend along the first direction D1. The semiconductor device 10 may have a structure in which the upper portion of the plurality of transistor structures (the first transistor structure FET1 and the second transistor structure FET2) including the upper portion active pattern (the first upper portion active pattern AP1_UT and the second upper portion active pattern AP2_UT) are isolated, through the second layer L2, from the lower portion of the plurality of transistor structures (the first transistor structure FET1 and the second transistor structure FET2) including the lower portion active pattern (the first lower portion active pattern AP1_BT and the second lower portion active pattern AP2_BT).

In an example embodiment, the gate cut film CT may penetrate the second work-function film WFM2 such that the second work-function film WFM2 is cut along the second direction D2. For example, the gate cut film CT may penetrate through the entire second work-function film WFM2. The second work-function film WFM2, which serves as the upper portion gate, may be cut and disposed along the second direction D2 by the gate cut film CT. By cutting the second work-function film WFM2 with the gate cut film CT, the semiconductor device 10 may have a structure in which the upper portion gate between the first transistor structure FET1 and the second transistor structure FET2 is isolated.

In an example embodiment, the bottom surface CT_BS (e.g., bottommost surface) of the gate cut film may be closer to the substrate 100 than an upper surface 115_US (e.g., uppermost surface) of the separating insulting film is to the substrate, at least in a region of the first transistor structure FET1.

In an example embodiment, the semiconductor device 10 may include a separating insulting film 115 disposed between the lower portion active pattern (a first lower portion active pattern AP1_BT and the second lower portion active pattern AP2_BT) and the upper portion active pattern (the first upper portion active pattern AP1_UT and the second upper portion active pattern AP2_UT). The separating insulting film 115 may include an insulating material. The separating insulting film 115 may be in contact with the second work-function film WFM2. Each transistor structure (e.g., first transistor structure FET1 and second transistor structure FET2) may include a separating insulating film 115 separating upper and lower portions thereof.

In an example embodiment, at least some of the plurality of transistor structures (the first transistor structure FET1 and the second transistor structure FET2) may include a common gate structure. For example, in some embodiments, the transistor structure including the common gate structure may be the first transistor structure FET1. In the present specification, the first transistor structure FET1 may be referred to as a common gate transistor structure. In an example embodiment, the common gate structure may include and result from a region where the first work-function film WFM1 and the second work-function film WFM2 contact each other. In another example embodiment, the common gate structure may include the first work-function film WFM1 and the second work-function film WFM2 being electrically connected, for example, based on a contact region where the first work-function film WFM1 and the second work-function film WFM2 contact each other.

In an example embodiment, at least some of the plurality of transistor structures (the first transistor structure FET1 and the second transistor structure FET2) may include a split gate structure. For example, in some embodiments, a transistor structure including a split gate structure may be the second transistor structure FET2. In the present specification, the second transistor structure FET2 may be referred to as a split gate transistor structure. In an example embodiment, the split gate structure may include the first work-function film WFM1 and the second work-function film WFM2 electrically separated (e.g., isolated) from each other. For example, the split gate structure may include the first work-function film WFM1 and the second work-function film WFM2 electrically and physically separated along the second direction D2, to be electrically isolated from each other. In an example embodiment, in the split gate structure, an upper surface WFM1_US (e.g., uppermost surface) of the first work-function film is closer to the substrate 100 than a bottom surface WFM2_BS (e.g., bottommost surface) of the second work-function film is to the substate 100.

In an example embodiment, the semiconductor device 10 includes a plurality of transistor structures, wherein at least some of the plurality of transistor structures may be the first transistor structure FET1. Further, the semiconductor device 10 may include a plurality of transistor structures, wherein at least some of the plurality of transistor structures may be the second transistor structure FET2. In an example embodiment, the semiconductor device 10 may include the first transistor structure FET1 and the second transistor structure FET2, for example in a repeated pattern.

The drawing illustrates that the first transistor structure FET1 includes the first lower portion active pattern AP1_BT and the first upper portion active pattern AP1_UT, and the second transistor structure FET2 includes the second lower portion active pattern AP2_BT and the second upper portion active pattern AP2_UT, but the illustration is only for convenience of explanation. The first active pattern AP1 includes the first lower portion active pattern AP1_BT and the first upper portion active pattern AP1_UT, and the second active pattern AP2 includes the second lower portion active pattern AP2_BT and the second upper portion active pattern AP2_UT. Example embodiments are described based on the drawings in which the semiconductor 10 includes the first transistor structure FET1 and the second transistor structure FET2, but in some embodiments, a plurality of transistor structures included in the semiconductor device 10 may all be the first transistor structures FET1 or may all be the second transistor structures FET2, wherein the transistor structures included are separated by the gate cut film. In these examples, the structure of FIG. 2 may still be used, except that the height of the first work function metal WFM1 may be the same for all transistors (e.g., to extend into the second work function metal WFM2 such as in the case of first transistor structure FET1, or to have a gap formed between the first work function metal WFM1 and the second work function metal WFM2 such as in the case of second transistor structure FET2).

In an example embodiment, the first transistor structure FET1 may include the separating insulting film 115 positioned between a lower portion active pattern AP1_BT (e.g., a first lower portion active pattern AP1_BT) and an upper portion active pattern AP1_UT (e.g., a first upper portion active pattern AP1_UT). In an example embodiment, the second transistor structure FET2 may include the separating insulting film 115 positioned between a lower portion active pattern AP2_BT (e.g., a second lower portion active pattern AP2_BT) and an upper portion active pattern AP2_UT (e.g., a second upper portion active pattern AP2_UT). The separating insulting film 115 included in the first transistor structure FET1 and the separating insulting film 115 included in the second transistor structure FET2 may be separated from each other. For example, the separating insulting film 115 included in the first transistor structure FET1 and the separating insulting film 115 included in the second transistor structure FET2 may be separated from each other with respect to the first direction D1. For example, each separating insulating film 115 may be formed of a particular material, and a different insulating material (e.g., a material that forms the second layer L2) may be formed therebetween.

In an example embodiment, in the first transistor structure FET1, the surface area of the region where the second work-function film WFM2 and the second layer L2 come into contact (e.g., an entire contact region where the second work-function film WFM2 and the second layer L2 contact each other) may be larger than the surface area of the region where the first work-function film WFM1 and the second work-function film WFM2 come into contact (e.g., an entire contact region where the first work-function film WFM1 and the second work-function film WFM2 contact each other).

In an example embodiment, in the first transistor structure FET1, in the second direction D2, the bottom surface WFM2_BS (e.g., bottommost surface) of the second work-function film may be closer to the substrate 100 than the upper surface WFM1_US (e.g., uppermost surface) of the first work-function film is to the substrate 100.

In an example embodiment, in the second transistor structure FET2, in the second direction D2, the length T₁ between the upper surface WFM1_US of the first work-function film and the bottom surface WFM2_BS of the second work-function film may be less than 5.8 nm, less than or equal to 5.6 nm, or less than or equal to 5.5 nm, and may be greater than 0, such as greater than 1 nm.

In an example embodiment, in the second transistor structure FET2, in the second direction D2, the ratio (T₁/T₂) of the length T₁ between the upper surface WFM1_US of the first work-function film and the bottom surface WFM2_BS of the second work-function film and the length T₂ of the separating insulting film 115 may be less than or equal to 0.5, less than or equal to 0.45, less than or equal to 0.4, less than or equal to 0.35, less than or equal to 0.3, less than or equal to 0.25, or less than or equal to 0.2. For example, the ratio T₁/T₂ may be 0.2 or greater and 0.5 or less.

Referring to FIG. 2 and FIG. 3, in an example embodiment, each of the first layer L1 and the second layer L2 may independently include an insulating material. Here, a portion of the first layer L1 may be disposed continuously in the first direction D1 between the plurality of transistor structures (the first transistor structure FET1 and the second transistor structure FET2). This may reduce the difficulty of the manufacturing process.

In an example embodiment, the first layer L1 may include an insulating material, and in the first transistor structure FET1, an upper surface L1_US (e.g., uppermost surface) of the first layer may be closer to the substrate 100 than the bottom surface WFM2_BS (e.g., bottommost surface) of the second work-function film is to the substrate 100.

In an example embodiment, the first layer L1 may include an insulating material, the semiconductor device 10 may include the first transistor structure FET1 and the second transistor structure FET2, and the thickness (e.g., a maximum thickness) of the second work-function film WFM2 in the second direction D2 of the first transistor structure FET1 may be substantially the same as the thickness (e.g., a maximum thickness) of the second work-function film WFM2 in the second direction D2 of the second transistor structure FET2.

Referring to FIG. 4 to FIG. 6, in an example embodiment, the first layer L1 may include a conductive material and the second layer L2 may include an insulating material. Here, a portion of the first layer L1 may be cut along the second direction D2 between the plurality of transistor structures (the first transistor structure FET1 and the second transistor structure FET2). In an example embodiment, when the contact area between the second layer L2 and the second work-function film WFM2 increases, the contact resistance may be increased, and the increase in contact resistance may be minimized by including a conductive material in the first layer L1. Further, by the first layer L1 including a conductive material between a plurality of transistor structures (the first transistor structure FET1 and the second transistor structure FET2) being cut along the second direction D2, there may be a structure in which the lower portion gate between the first transistor structure FET1 and the second transistor structure FET2 is isolated.

In an example embodiment, the first layer L1 may include conductive material, and in the first transistor structure FET1, the bottom surface WFM2_BS of the second work-function film may be closer to the substrate 100 than the upper surface L1_US of the first layer is to the substrate 100.

In an example embodiment, the first layer L1 may include a conductive material, the semiconductor device 10 may include the first transistor structure FET1 and the second transistor structure FET2, and the thickness of the second work-function film WFM2 (e.g., maximum thickness) in the second direction D2 of the first transistor structure FET1 may be greater than the thickness of the second work-function film WFM2 (e.g., maximum thickness) in the second direction D2 of the second transistor structure FET2.

In an example embodiment, the first layer L1 may include a conductive material, and in the first transistor structure FET1, the first work-function film WFM1 may include a concave portion WMF1_G at the interface with the second work-function film WFM2, as can be seen for example in FIG. 6.

In an example embodiment, the semiconductor device 10 may include a plurality of wiring lines WL. The wiring lines WL may include a power line that supplies power to the semiconductor device 10 and a signal line that transmits an electrical signal. In an example embodiment, the wiring lines WL may each have a single-layer structure, but as illustrated, the wiring lines WL may have a multilayer structure including a wiring filling film WL_f and a wiring barrier film WL_b. In an example embodiment, the wiring filling film WL_f may include one selected from the group consisting of aluminum (Al), tungsten (W), cobalt (Co), ruthenium (Ru), copper (Cu), silver (Ag), gold (Au), manganese (Mn), and molybdenum (Mo). In an example embodiment, the wiring barrier film WL_b may include at least one selected from the group consisting of tantalum (Ta) and tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) and 2D material. In the present disclosure, the 2D material may be a metallic material and/or a semiconductor material. The 2D material may include a 2D allotrope or a 2D compound. For example, the 2D material may include at least one of graphene, molybdenum disulfide (MoS₂), molybdenum diselenide (MoSe₂), tungsten diselenide (WSe₂) and tungsten disulfide (WS₂), but the 2D material is not limited thereto. In other words, the above-described 2D materials are only listed as examples, and therefore, the 2D materials that may be included in the semiconductor device 10 of the present disclosure are not limited by the above-described materials.

In an example embodiment, the semiconductor device 10 may include gate contacts CB. The gate contacts CB may be electrically connected to the wiring lines WL, and may allow the second work-function film WFM2 to be electrically connected to the wiring lines WL. In an example embodiment, each gate contact CB may have a single-layer structure, but as illustrated in the drawing, the gate contact CB may have a multilayer structure including a gate contact filling film CB_f and a gate contact barrier film CB_b. In an example embodiment, with respect to materials included in the gate contact filling film CB_f, the materials included in the aforementioned wiring filling film WL_f may be referenced. In an example embodiment, with respect to a material included in the gate contact barrier film CB_b, reference may be made to the materials included in the aforementioned wiring barrier film WL_b.

In an example embodiment, a portion of the gate contact CB may be disposed in the gate capping film GP. The gate capping film GP may be disposed on the first active pattern AP1 and the second active pattern AP2. The gate contact CB may be disposed to penetrate the gate capping film GP in the second direction D2. The gate capping film GP may be disposed on the second work-function film WFM2. In an example embodiment, the gate capping film GP may include an insulating material.

In an example embodiment, the semiconductor device 10 may include an insulating film ILD1 between layers disposed on the gate capping film GP. A portion of the gate contact CB may be disposed between portions of the insulating film ILD1. The gate contact CB may be disposed to pass through at least a portion of the insulating film ILD1 in the second direction D2. The insulating film ILD1 may include an insulating material. For example, the insulating film ILD1 may include at least one selected from the group consisting of silicon oxide, silicon-germanium oxide, germanium oxide, silicon oxynitride, silicon nitride and a low-k material. The insulating film ILD1 may be formed of a plurality of consecutively deposited layers so that the gate contact CB passes through the consecutive layers.

In an example embodiment, the semiconductor device 10 may have a first etching-stopping film ES1 disposed between the insulating film ILD1 and the gate capping film GP. The first etching-stopping film ES1 may include at least one selected from the group consisting of silicon nitride (SiN), silicon oxynitride (SiON), silicon oxycarbonitride (SiOCN), silicon boron nitride (SiBN), silicon oxyboron nitride (SiOBN) and silicon oxycarbide (SiOC). The gate contact CB may be disposed to penetrate the first etching-stopping film ES1 in the second direction D2.

In an example embodiment, the semiconductor device 10 may include an insulating film ILD2 between layers disposed on the insulating film ILD1. At least a portion of the wiring line WL may be disposed in the insulating film ILD2. The insulating film ILD2 may be formed of a plurality of consecutively deposited layers so that the portion of the wiring line WL passes through the consecutive layers The wiring line WL may be disposed to pass through at least a portion of the insulating film ILD2 in the second direction D2. The insulating film ILD2 may include an insulating material. For example, the insulating film ILD2 may include at least one selected from the group consisting of silicon oxide, silicon-germanium oxide, germanium oxide, silicon oxynitride, silicon nitride and a low-k material.

In an example embodiment, the semiconductor device 10 may include a second etching-stopping film ES2 disposed between the insulating film ILD2 and the insulating film ILD1. The second etching-stopping film ES2 may include at least one selected from the group consisting of silicon nitride (SiN), silicon oxynitride (SiON), silicon oxycarbonitride (SiOCN), silicon boron nitride (SiBN), silicon oxyboron nitride (SiOBN) and silicon oxycarbide (SiOC). The wiring line WL may be disposed to penetrate the second etching-stopping film ES2 in the second direction D2.

In an example embodiment, with respect to the method for manufacturing the semiconductor device 10, any method already known for known components may be applied as long as it is not contradictory to the method described below. Below, a method for securing the structural features of the aforementioned semiconductor device 10 will be mainly described.

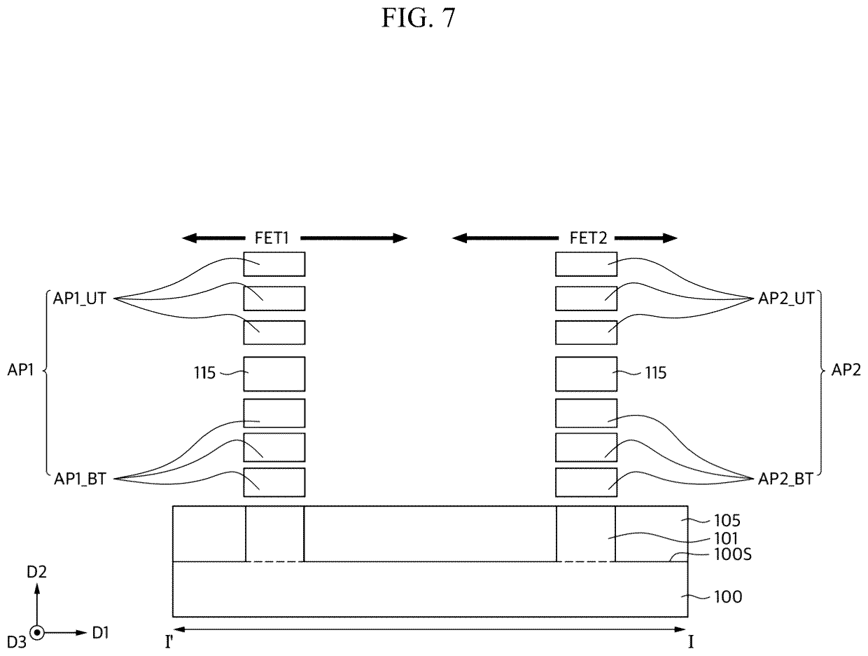

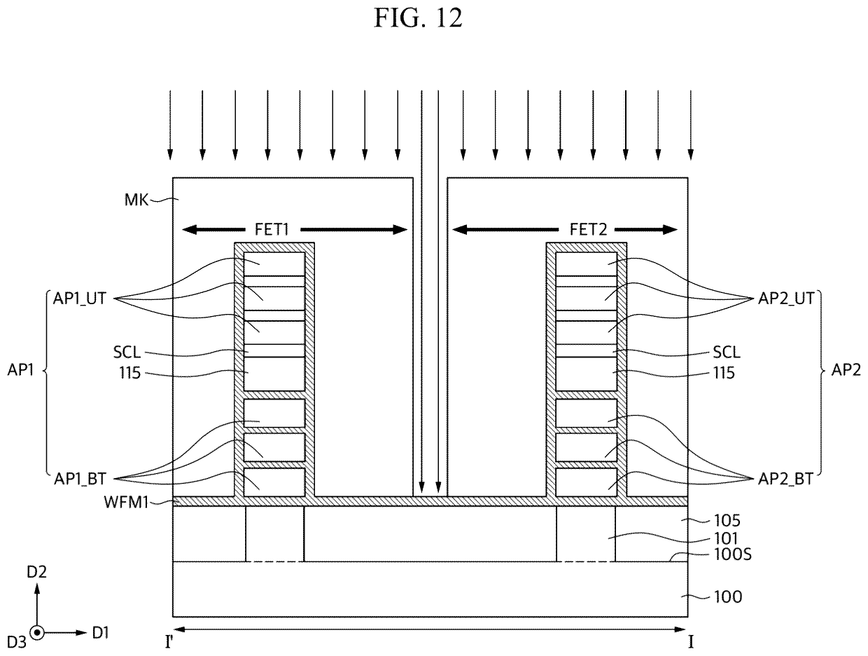

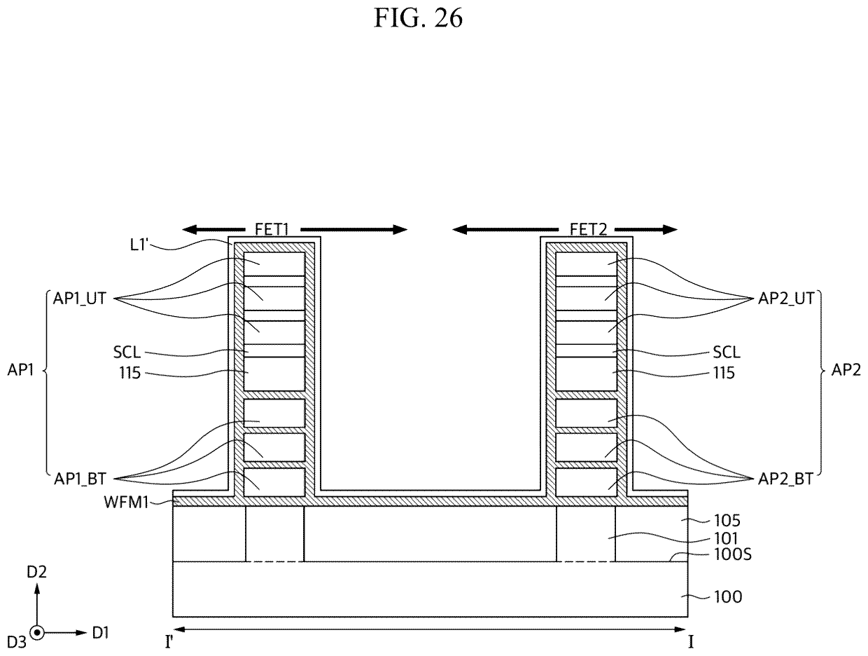

FIG. 7 to FIG. 11 are for explaining some methods of manufacturing the semiconductor device 10 according to the first and second example embodiments of the present disclosure. FIG. 12 to FIG. 25 are for explaining some of the manufacturing methods of the semiconductor device 10 according to the first example embodiment of the present disclosure. FIG. 26 to FIG. 40 are for explaining some methods of manufacturing the semiconductor device 10 according to the second example embodiment of the present disclosure. Hereinafter, described are example embodiments in which the semiconductor device 10 is manufactured to include both the first transistor structure FET1 and the second transistor structure FET2. However, those skilled in the art of the present disclosure may easily implement the semiconductor device 10 by referring to the description below even if the semiconductor device 10 includes only the first transistor structure FET1 or only the second transistor structure FET2.

In the present disclosure, although the film or layer is not particularly limited, in an example embodiment, a specific film or layer may be formed through deposition. The deposition may be performed by, for example, chemical vapor deposition (CVD), physical vapor deposition (PVD), or atomic layer deposition (ALD). If there is another method used in the art other than depositing a specific film or layer, it may be applied. Further, in the present disclosure, although not particularly limited, certain films or layers may be removed by etching, in an example embodiment. For example, etching may be performed by dry etching or wet etching using phosphoric acid.

FIG. 7 illustrates a method for manufacturing the semiconductor device 10 according to an example embodiment including the first transistor structure FET1 to include a common gate structure and the second transistor structure FET2 to include a split gate structure, with the dummy gate structure surrounding the active patterns (the first active pattern AP1 and the second active pattern AP2) removed.

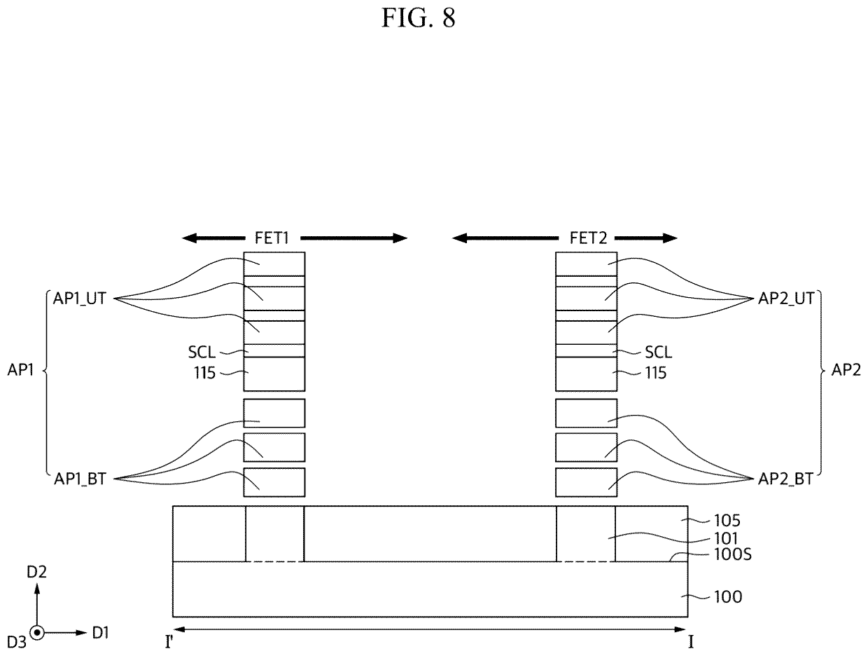

Referring to FIG. 8, in an example embodiment, a method for manufacturing the semiconductor device 10 may include forming a sacrificial film SCL between the upper portion active patterns (the first upper portion active pattern AP1_UT and the second upper portion active pattern AP2_UT) while the dummy gate structure surrounding the active patterns (the first active pattern AP1 and the second active pattern AP2) is removed. The sacrificial film SCL formed between the upper portion active patterns (the first upper portion active pattern AP1_UT and the second upper portion active pattern AP2_UT) may include lanthanum oxide (LaO), but the sacrificial film SCL is not limited thereto. Here, there may be a blank space between the lower portion active patterns (the first lower portion active pattern AP1_BT and the second lower portion active pattern AP2_BT). Even though not illustrated, in order to form the lower portion active patterns (the first lower portion active pattern AP1_BT and the second lower portion active pattern AP2_BT), a sacrificial film is formed between them, and when the sacrificial film is removed, a void space may be formed. At this time, the sacrificial film may include, but is not limited to, aluminum oxide (AlO).

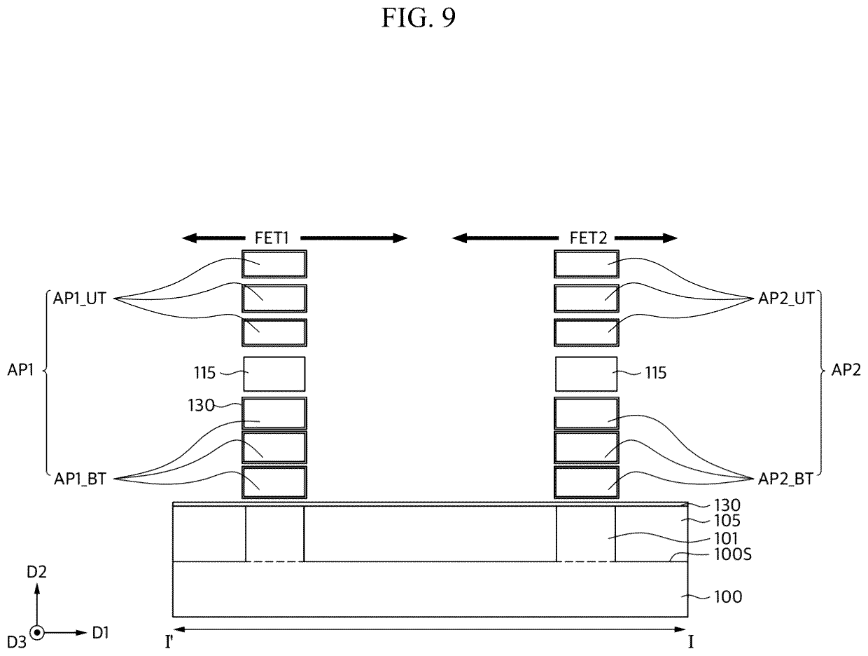

Referring to FIG. 9, in an example embodiment, a method for manufacturing the semiconductor device 10 may include forming the gate dielectric film 130. The gate dielectric film 130 may include an insulating material. The gate dielectric film 130 may be disposed to extend along the upper surface of the field insulating film 105 and the upper surface of the fin type pattern 101, and may be disposed to surround the first active pattern AP1 and the second active pattern AP2.

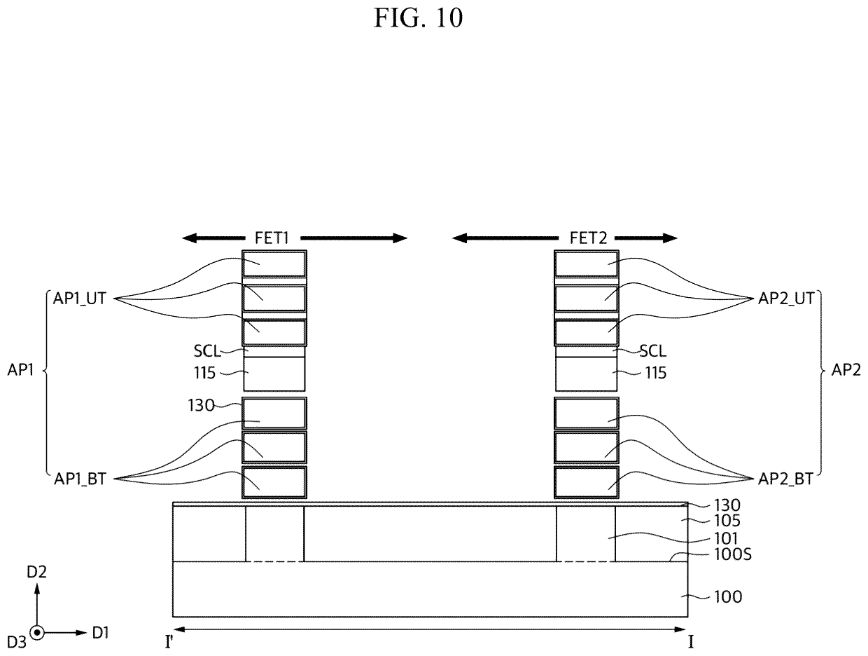

Referring to FIG. 10, in an example embodiment, a method for manufacturing the semiconductor device 10 may include forming the sacrificial film SCL between the upper portion active patterns (the first upper portion active pattern AP1_UT and the second upper portion active pattern AP2_UT) after forming the gate dielectric film 130. For an explanation thereof, the description with reference to FIG. 8 may be referred to.

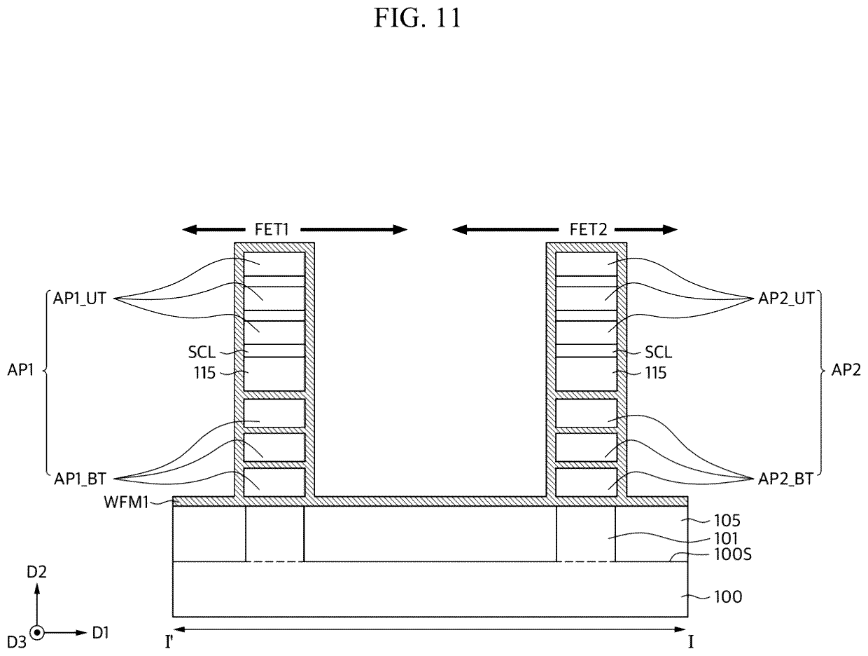

Hereinafter, example embodiments with respect to FIG. 11 to FIG. 40 are described except the description regarding the gate dielectric film 130 for convenience of explanation, but it will be apparent to those skilled in the art that the semiconductor device 10 may include the gate dielectric film 130 with reference to FIG. 9 and FIG. 10. Referring to FIG. 11, in an example embodiment, a method for manufacturing the semiconductor device 10 may include forming the first work-function film WFM1. The first work-function film WFM1 is formed by overall deposition, and may fill the void formed between the lower portion active patterns (the first lower portion active pattern AP1_BT and the second lower portion active pattern AP2_BT).

Referring to FIG. 12, in an example embodiment, a method for manufacturing the semiconductor device 10 may include forming a mask MK leaving some space between the first transistor structure FET1 and the second transistor structure FET2, and removing the first work-function film WFM1 in the region where the mask MK is not formed.

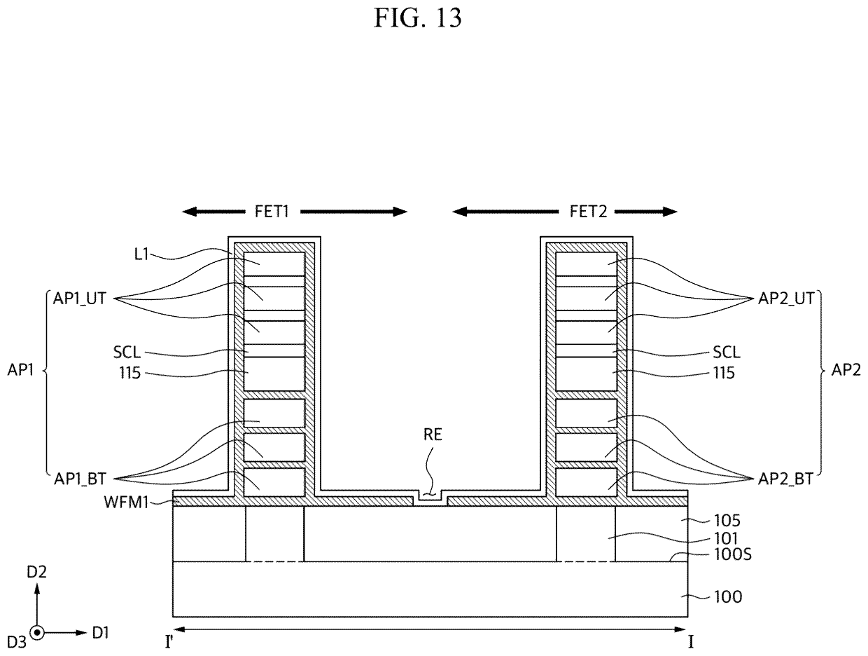

Referring to FIG. 13, in an example embodiment, a method for manufacturing the semiconductor device 10 may include forming a recess RE by cutting a portion of the first work-function film WFM1 disposed between the first transistor structure FET1 and the second transistor structure FET2. For example, the method for manufacturing the semiconductor device 10 may include forming the recess RE by removing the first work-function film WFM1 in the region where the mask MK is not formed. In an example embodiment, the method for manufacturing the semiconductor device 10 may include depositing the first layer L1 including an insulating material. In some embodiments, the first layer L1 may be formed with a thickness that does not completely fill the recess RE.

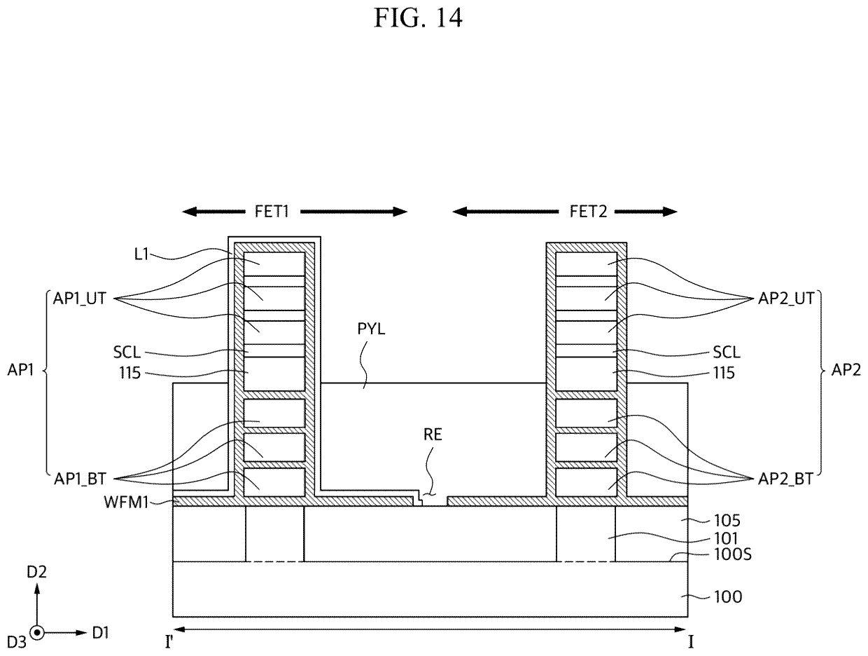

Referring to FIG. 14, in an example embodiment, a method for manufacturing the semiconductor device 10 may include removing the first layer L1 formed in the second transistor structure FET2. In an example embodiment, the method of manufacturing the semiconductor device 10 may include forming a polymer layer PYL. For example, the polymer layer PYL may include a polymer-based material for bottom anti-reflective coating (BARC). However, the polymer layer PYL may include a spin-on-hardmask (SOH) material such as silicon oxide even if it is not a polymer.

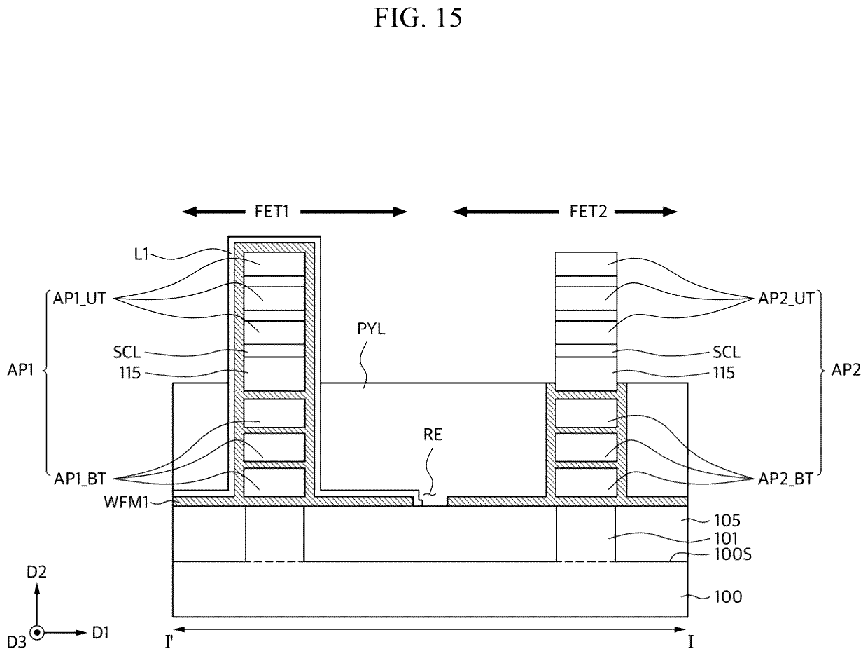

Referring to FIG. 15, in an example embodiment, a method for manufacturing the semiconductor device 10 may include removing a portion of the first work-function film WFM1 formed on the second transistor structure FET2.

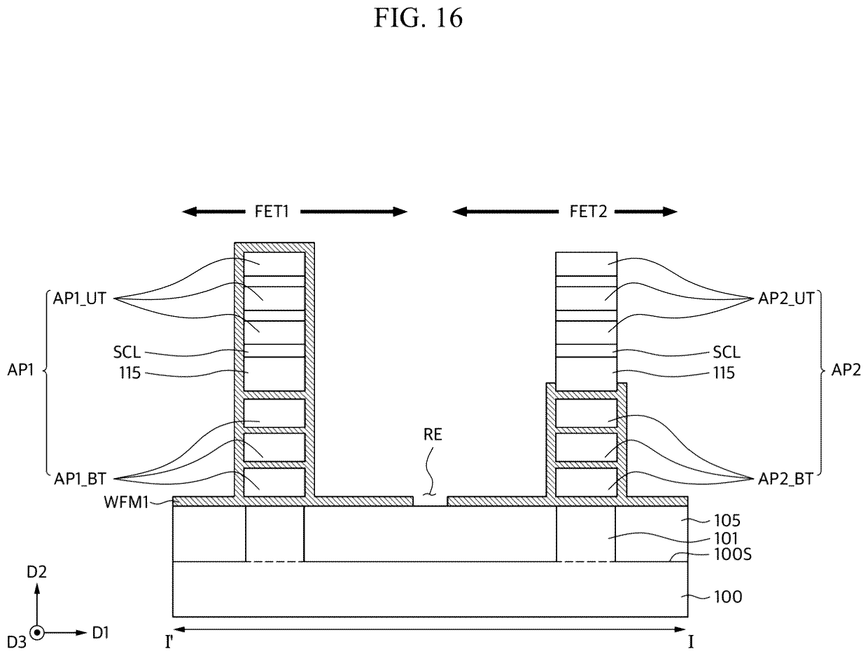

Referring to FIG. 16, in an example embodiment, a method for manufacturing the semiconductor device 10 may include removing the polymer layer PYL. In the example embodiment, a method for manufacturing the semiconductor device 10 may include removing the first layer L1 formed in the first transistor structure FET1.

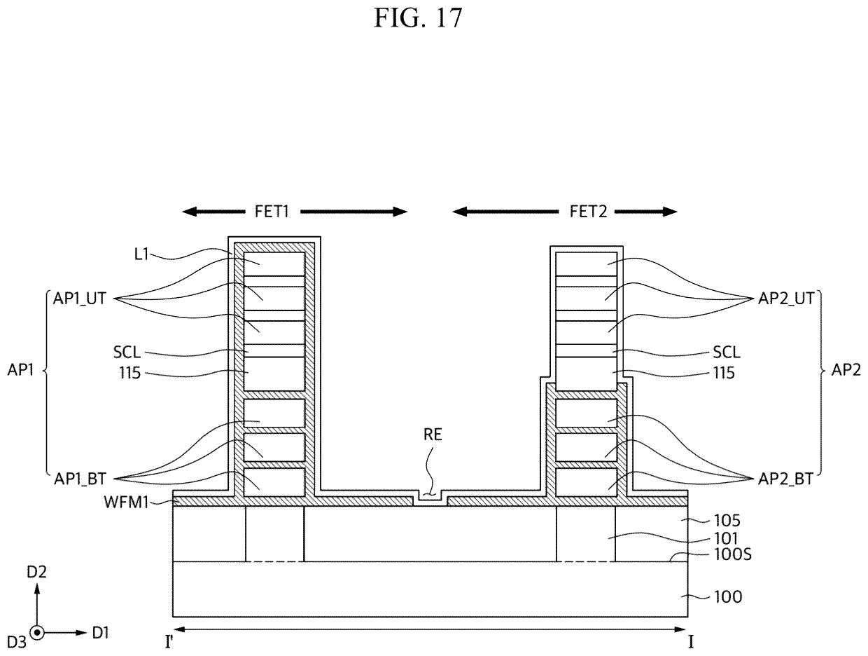

Referring to FIG. 17, in an example embodiment, a method for manufacturing the semiconductor device 10 may include re-depositing the first layer L1 including the insulating material. In one embodiment, the first layer L1 may be formed with a thickness that does not completely fill the recess RE. In one embodiment, the first layer L1 may be deposited in the recess to have a top surface lower than a top surface of the first layer L1 immediately adjacent to and outside the recess.

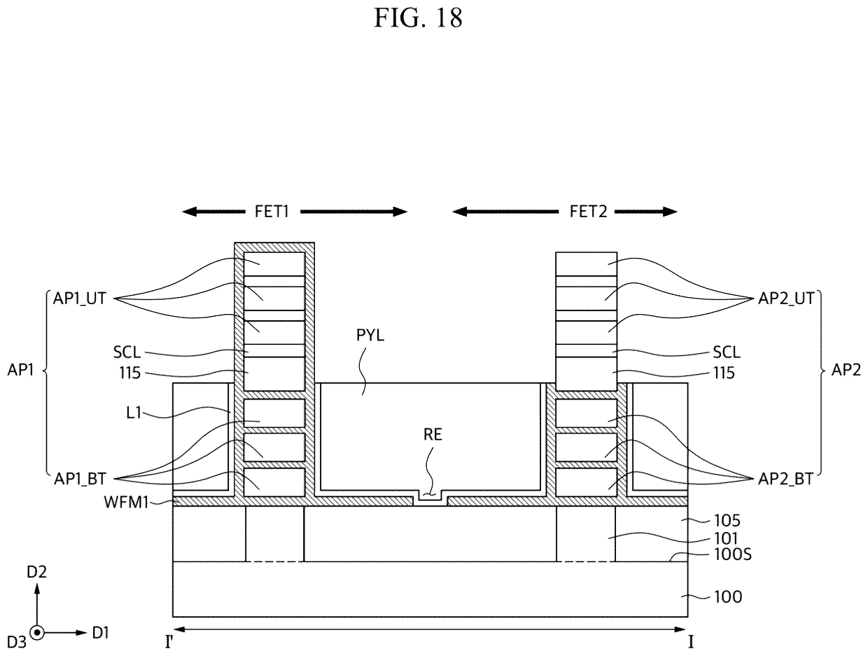

Referring to FIG. 18, in an example embodiment, a method for manufacturing the semiconductor device 10 may include forming the polymer layer PYL. In an example embodiment, a method for manufacturing the semiconductor device 10 may include removing a portion of the first layer L1 formed in the first transistor structure FET1 and the second transistor structure FET2.

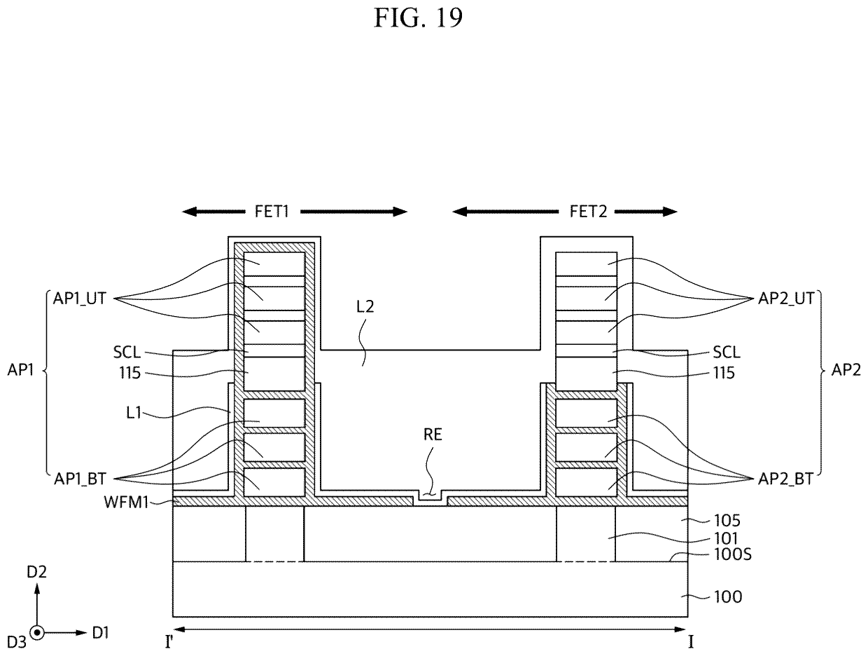

Referring to FIG. 19, in an example embodiment, a method for manufacturing the semiconductor device 10 may include removing the polymer layer PYL. In an example embodiment, a method for manufacturing the semiconductor device 10 may include depositing the second layer L2 including an insulating material. In an example embodiment, the second layer L2 may be deposited so as to fill the recess RE while providing isolation between the upper portion active pattern (the first upper portion active pattern AP1_UT and the second upper portion active pattern AP2_UT) and the lower portion active pattern (the first lower portion active pattern AP1_BT and the second lower portion active pattern AP2_BT).

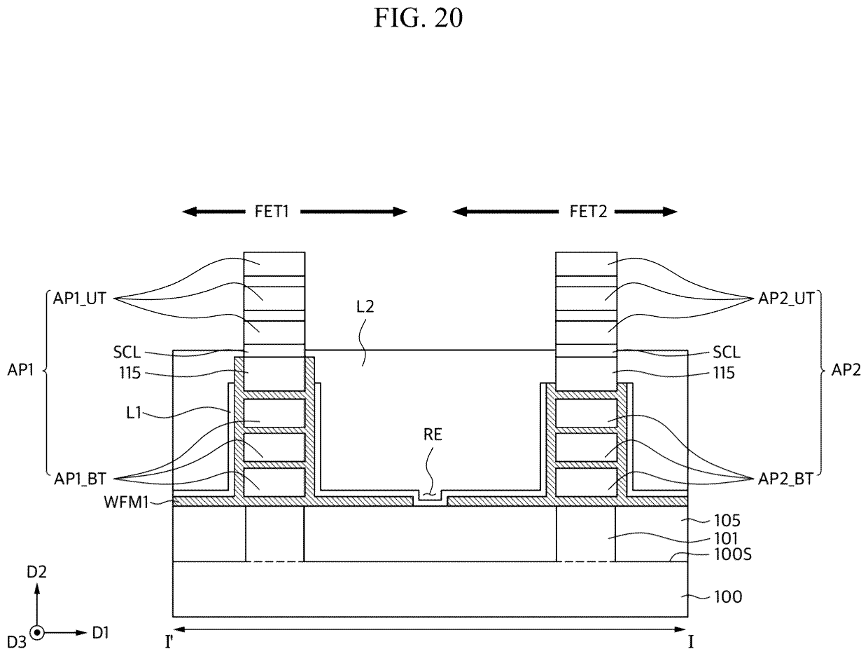

Referring to FIG. 20, in an example embodiment, a method for manufacturing the semiconductor device 10 may include removing a portion of the second layer L2 formed in the first transistor structure FET1 and the second transistor structure FET2. The second layer L2 formed on the upper portion of the first transistor structure FET1 and the second transistor structure FET2 may be removed. In an example embodiment, a method for manufacturing the semiconductor device 10 may include removing a portion of the first work-function film WFM1 formed on the first transistor structure FET1. Therefore, the first work-function film WFM1 formed on the upper side of the first transistor structure FET1 may be removed.

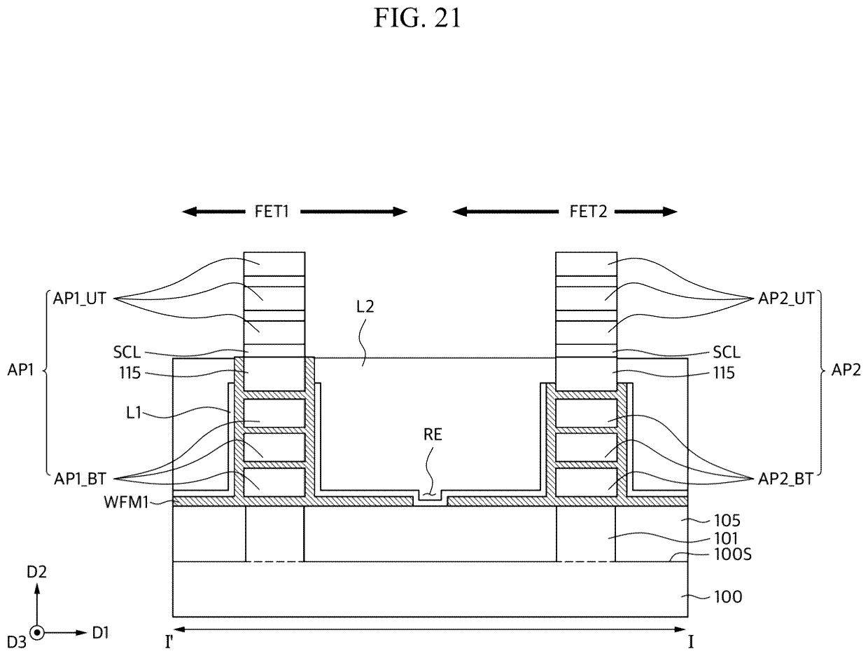

Referring to FIG. 21, in an example embodiment, a method for manufacturing the semiconductor device 10 may include removing a portion of the second layer L2 in order for the first work-function film WFM1 to be exposed from the second layer L2 in the first transistor structure FET1.

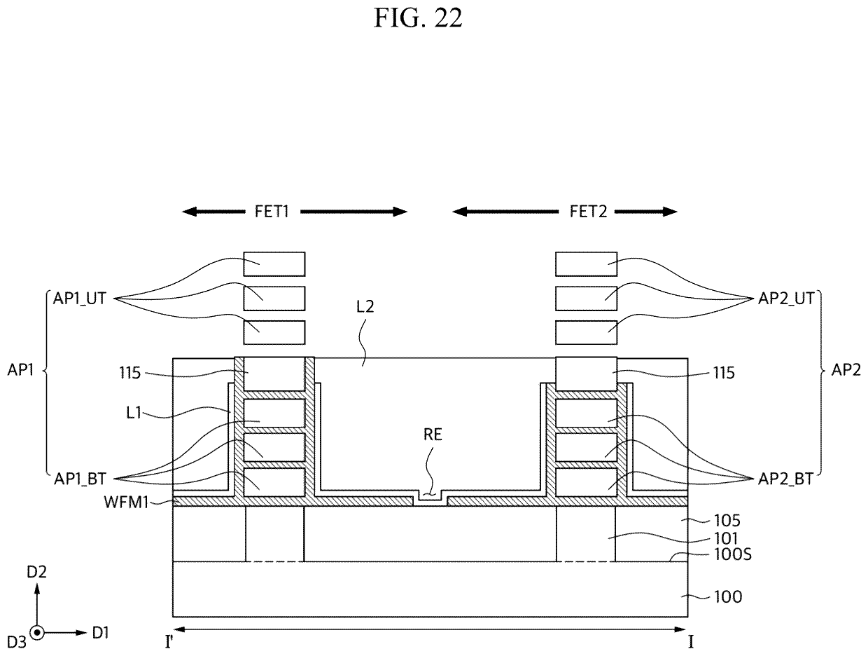

Referring to FIG. 22, in an example embodiment, a method for manufacturing the semiconductor device 10 may include removing the sacrificial film SCL formed between the upper portion active patterns (the first upper portion active pattern AP1_UT and the second upper portion active pattern AP2_UT).

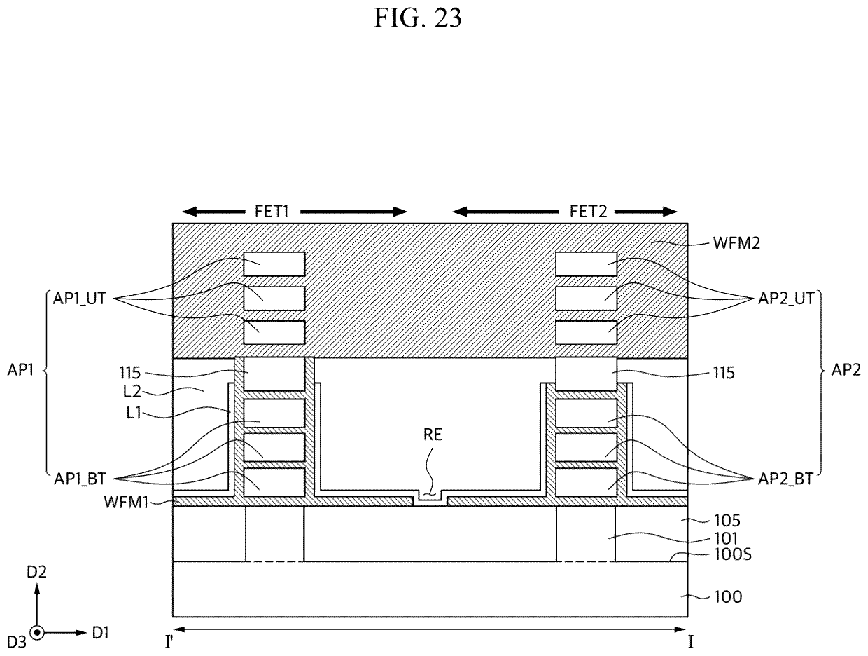

Referring to FIG. 23, in an example embodiment, a method for manufacturing the semiconductor device 10 may include forming the second work-function film WFM2 on the second layer L2.

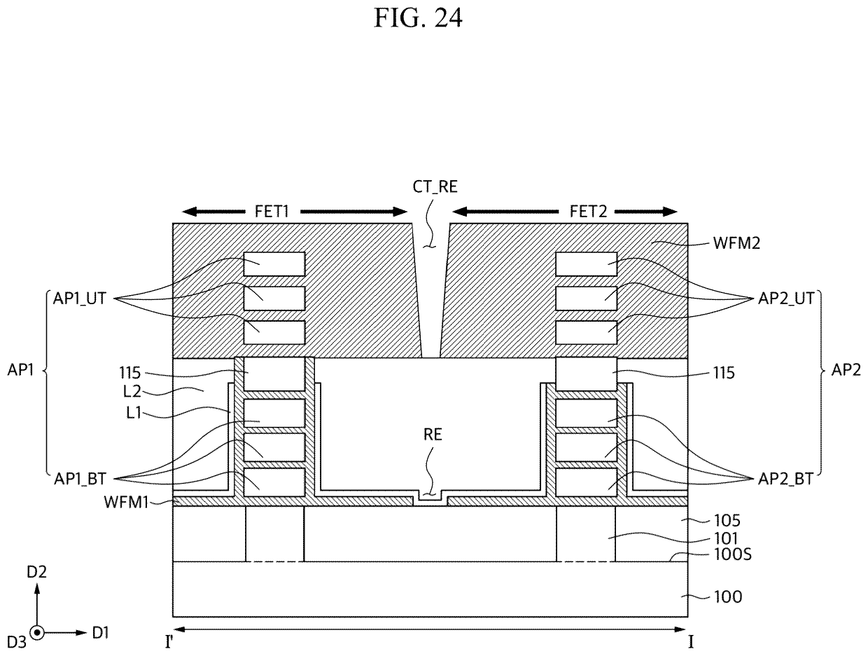

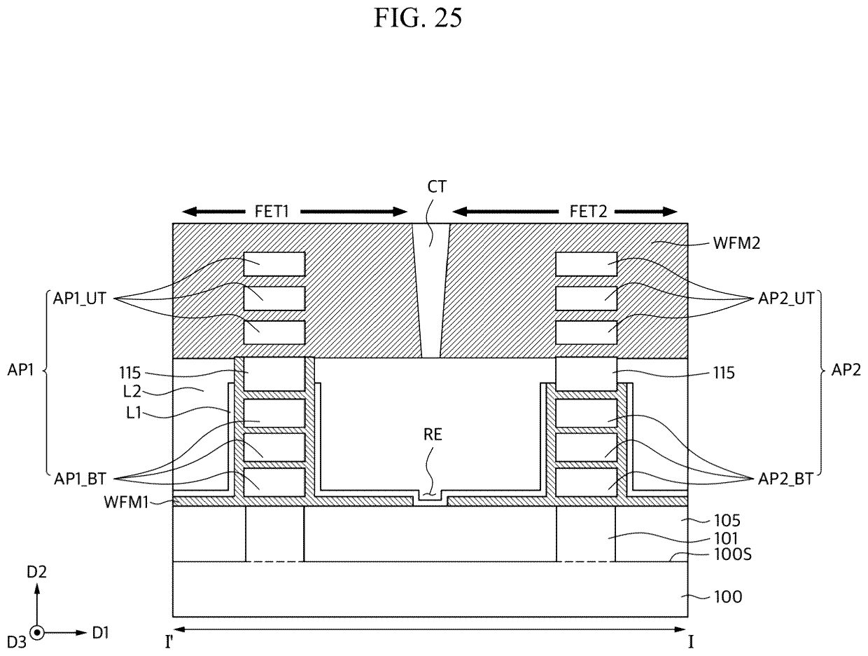

Referring to FIG. 24 and FIG. 25, in an example embodiment, a method for manufacturing the semiconductor device 10 may include forming a cut recess CT_RE by removing a portion of the second work-function film WFM2 disposed between the first transistor structure FET1 and the second transistor structure FET2. The cut recess CT_RE may include removing the second work-function film WFM2 along the second direction D2. Here, when the second work-function film WFM2 is being removed, the cut recess CT_RE may gradually decrease in length in the first direction D1 as the cut recess CT_RE approaches the substrate 100. In an example embodiment, a method for manufacturing the semiconductor device 10 may include forming the gate cut film CT by filling the formed cut recess CT_RE with an insulating material.

For description with respect to FIG. 26 to FIG. 40 below, if not contradictory, the descriptions with reference to FIG. 12 to FIG. 25 may be referred to.

Referring to FIG. 26, in an example embodiment, a method for manufacturing the semiconductor device 10 may include depositing a layer 1′ L1′ including insulating material. For example, the layer 1′ L1′ may include the same material as the first layer L1 deposited in the description of FIG. 13.

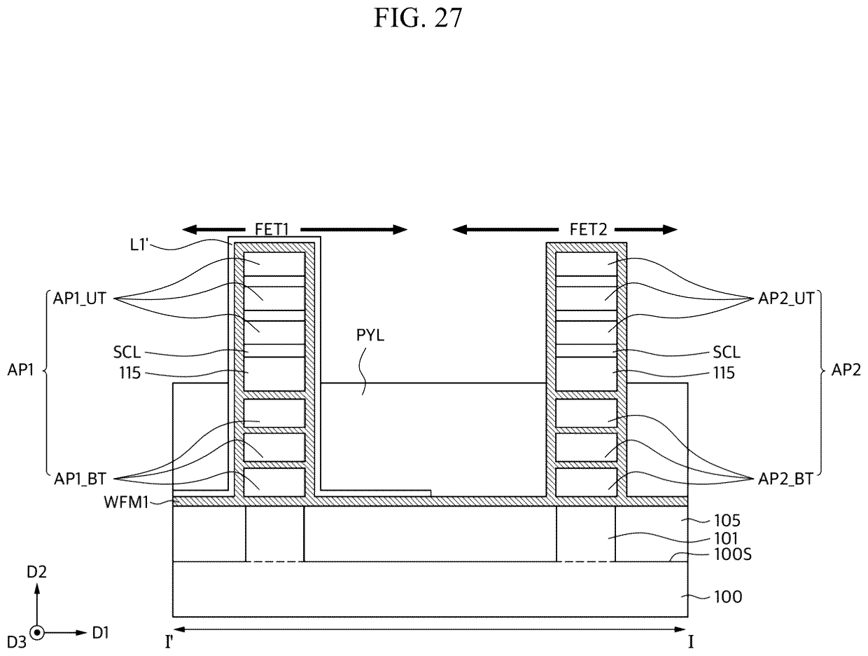

Referring to FIG. 27, in an example embodiment, a method for manufacturing the semiconductor device 10 may include removing the layer 1′ L1′ formed in the second transistor structure FET2. In an example embodiment, a method for manufacturing the semiconductor device 10 may include forming the polymer layer PYL.

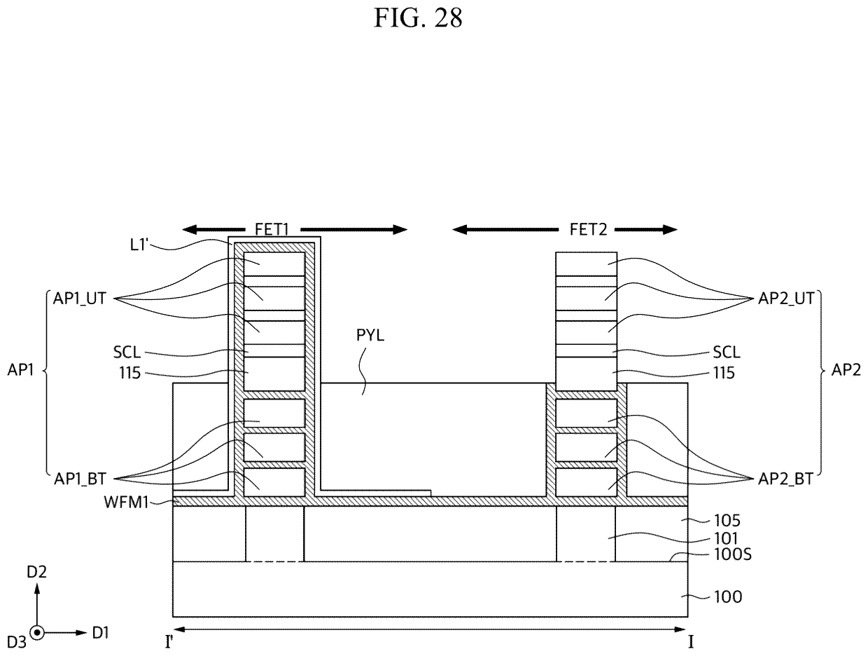

Referring to FIG. 28, in an example embodiment, a method for manufacturing the semiconductor device 10 may include removing a portion of the first work-function film WFM1 formed on the second transistor structure FET2.

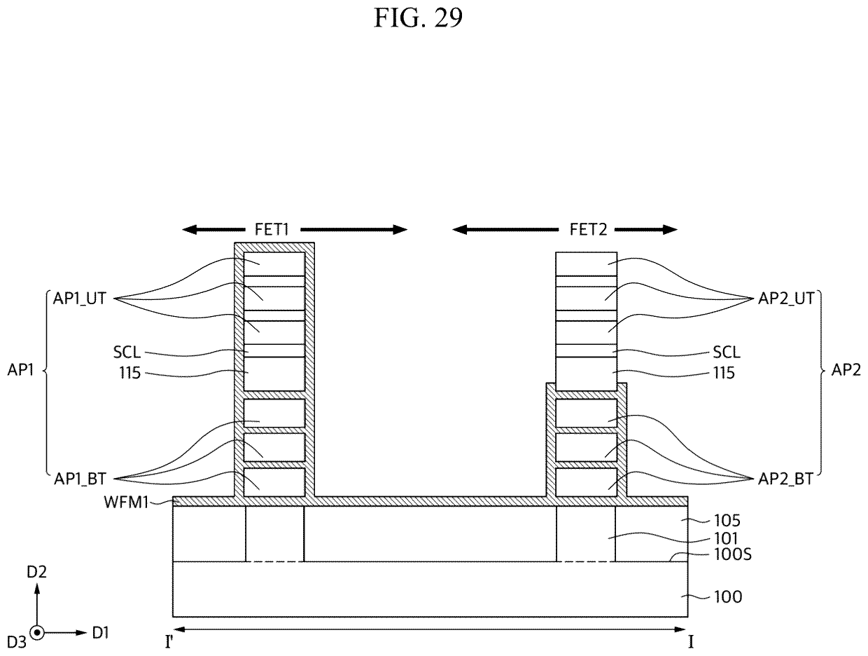

Referring to FIG. 29, in an example embodiment, a method for manufacturing the semiconductor device 10 may include removing the polymer layer PYL. In an example embodiment, a method for manufacturing the semiconductor device 10 may include removing the layer L1′ formed in the first transistor structure FET1.

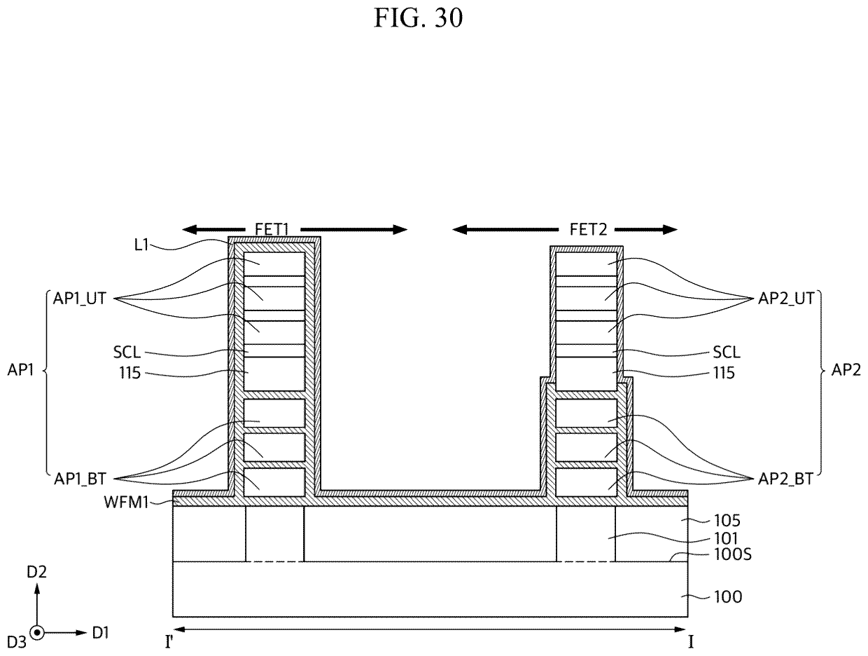

Referring to FIG. 30, in an example embodiment, a method for manufacturing the semiconductor device 10 may include depositing the first layer L1 including a conductive material.

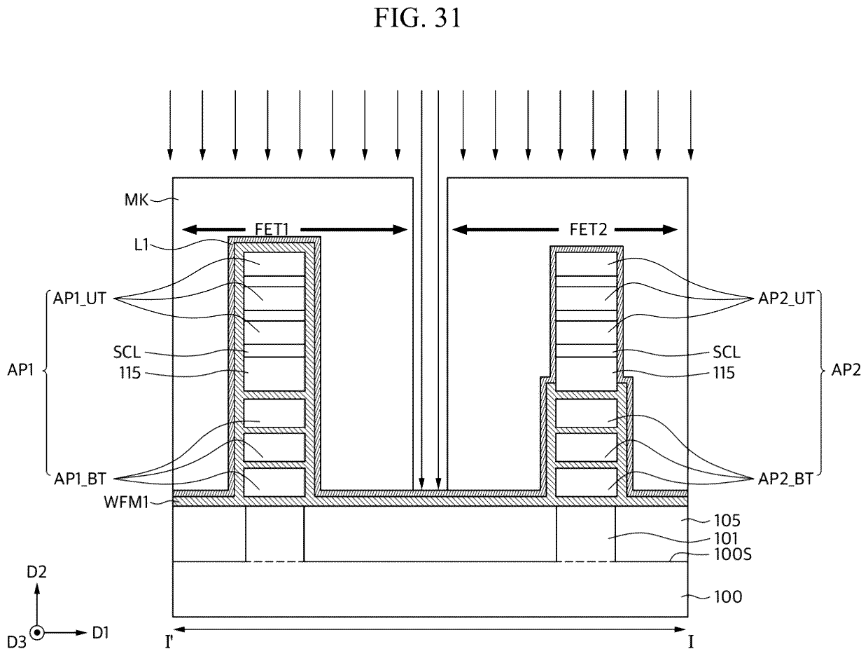

Referring to FIG. 31, in an example embodiment, a method for manufacturing the semiconductor device 10 may include forming the mask MK leaving a portion between the first transistor structure FET1 and the second transistor structure FET2, and removing the first work-function film WFM1 and the first layer L1 in the region where the mask MK is not formed.

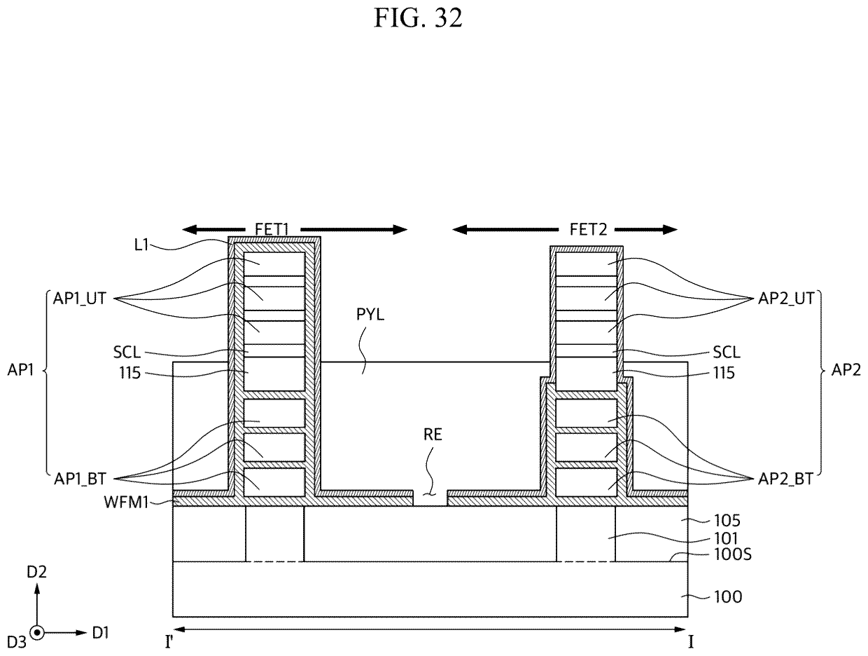

Referring to FIG. 32, in an example embodiment, a method for manufacturing the semiconductor device 10 may include forming the recess RE by cutting a portion of the first work-function film WFM1 and the first layer L1 disposed between the first transistor structure FET1 and the second transistor structure FET2. In other words, the method for manufacturing the semiconductor device 10 may include forming the recess RE by removing the first work-function film WFM1 and the first layer L1 of the region where the mask MK is not formed. In an example embodiment, a method for manufacturing the semiconductor device 10 may include forming the polymer layer PYL.

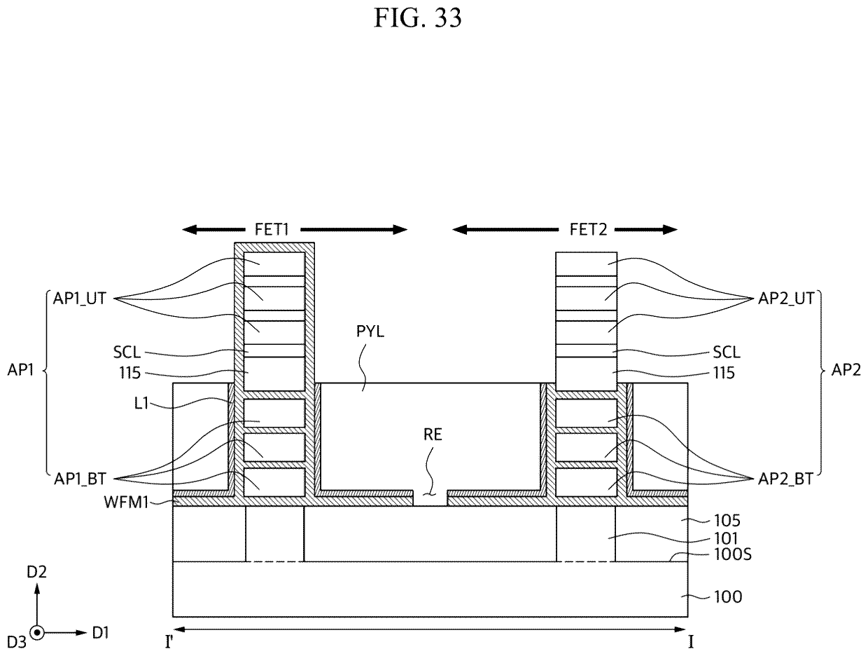

Referring to FIG. 33, in an example embodiment, a method for manufacturing the semiconductor device 10 may include removing a portion of the first layer L1 formed in the first transistor structure FET1 and the second transistor structure FET2.

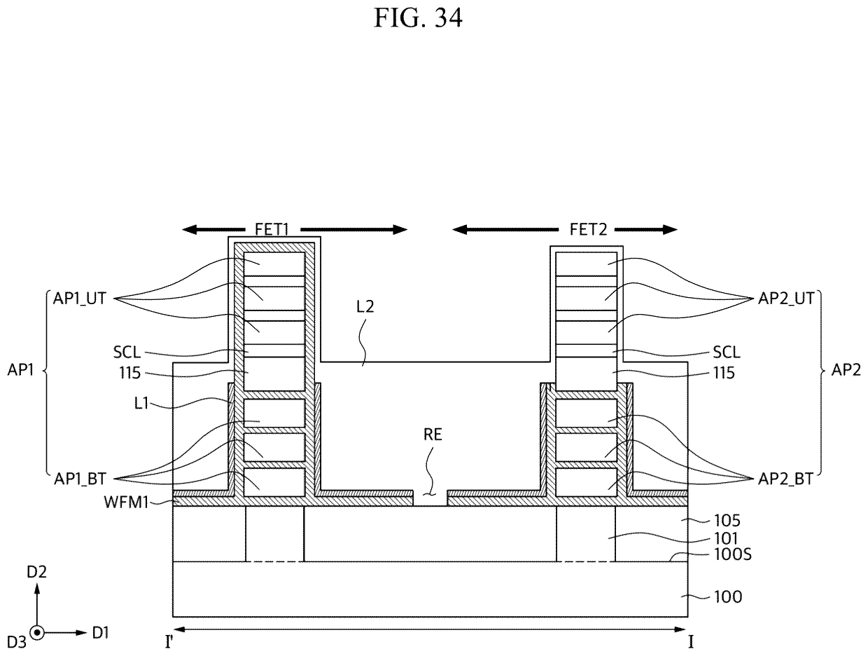

Referring to FIG. 34, in an example embodiment, a method for manufacturing the semiconductor device 10 may include removing the polymer layer PYL. In an example embodiment, a method for manufacturing the semiconductor device 10 may include depositing the second layer L2 including an insulating material. In an example embodiment, the second layer L2 may be deposited so as to fill the recess RE while providing isolation between the upper portion active pattern (the first upper portion active pattern AP1_UT and the second upper portion active pattern AP2_UT) and the lower portion active pattern (the first lower portion active pattern AP1_BT and the second lower portion active pattern AP2_BT).

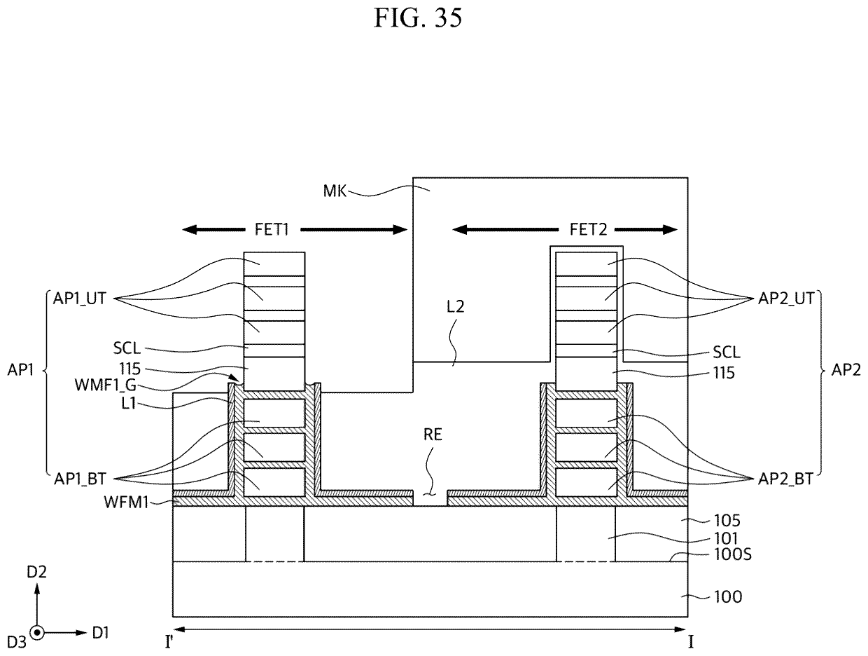

Referring to FIG. 35, in an example embodiment, a method for manufacturing the semiconductor device 10 may include forming the mask MK while leaving the first transistor structure FET1 region, and removing a portion of the second layer L2 so that the first layer L1 is exposed from the second layer L2 in the first transistor structure FET1. The second layer L2 formed on the upper side of the first transistor structure FET1 may be removed. In an example embodiment, the method for manufacturing the semiconductor device 10 may include removing a portion of the first work-function film WFM1 formed on the first transistor structure FET1. For example, the first work-function film WFM1 formed on the upper side of the first transistor structure FET1 may be removed. Here, as the portion of the first work-function film WFM1 is removed, in the first transistor structure FET1, the first work-function film WFM1 may form the concave portion WMF1_G at the interface with the second work-function film WFM2.

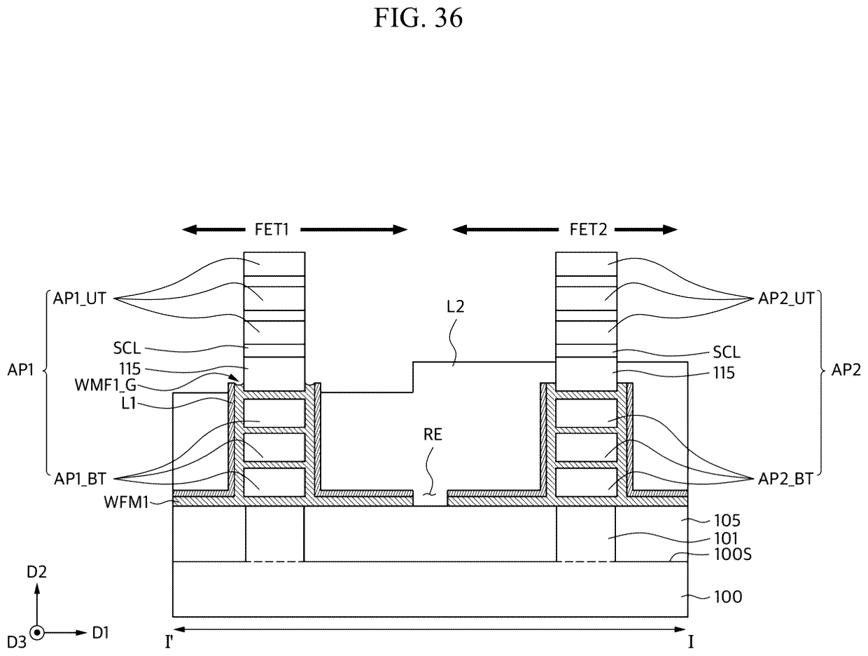

Referring to FIG. 36, in an example embodiment, a method for manufacturing the semiconductor device 10 may include, after removing the mask MK, removing a portion of the second layer L2 formed in the second transistor structure FET2. For example, the second layer L2 formed on the upper side of the second transistor structure FET2 may be removed.

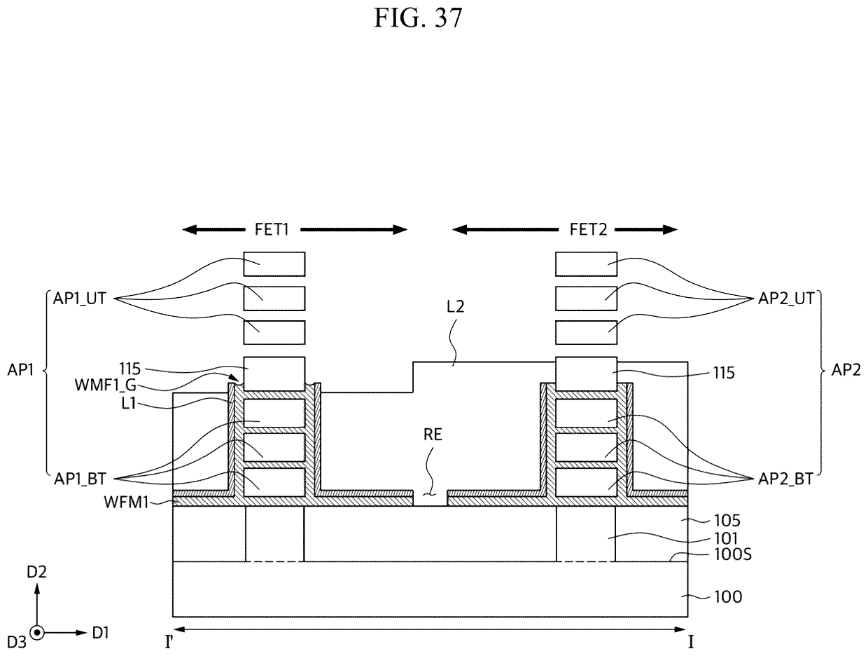

Referring to FIG. 37, in an example embodiment, a method for manufacturing the semiconductor device 10 may include removing the sacrificial film SCL formed between the upper portion active patterns (the first upper portion active pattern AP1_UT and the second upper portion active pattern AP2_UT).

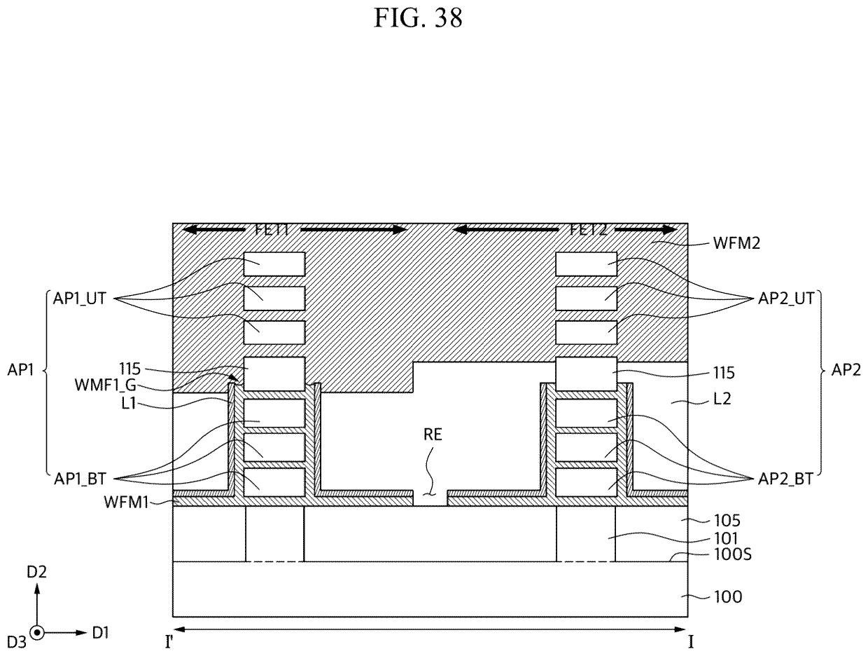

Referring to FIG. 38, in an example embodiment, a method for manufacturing the semiconductor device 10 may include forming the second work-function film WFM2 on the second layer L2.

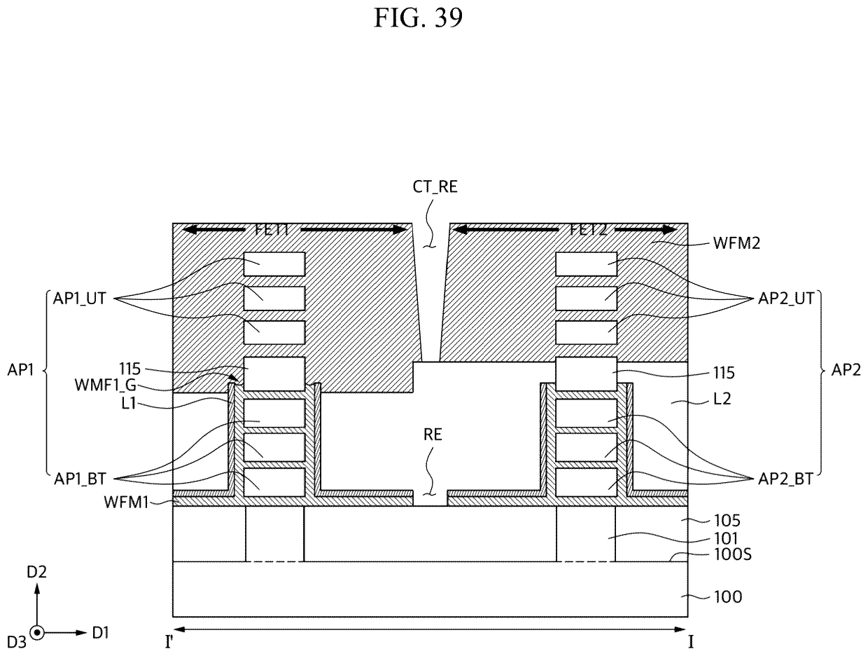

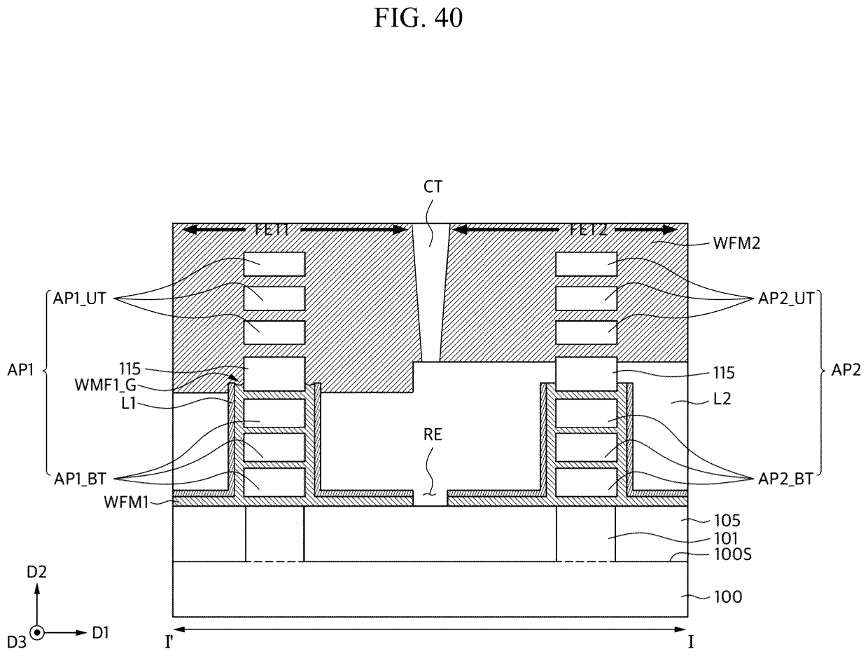

Referring to FIG. 39 and FIG. 40, in an example embodiment, a method for manufacturing the semiconductor device 10 may include forming the cut recess CT_RE by removing a portion of the second work-function film WFM2 disposed between the first transistor structure FET1 and the second transistor structure FET2. The cut recess CT_RE may include removing the second work-function film WFM2 along the second direction D2. Here, when the second work-function film WFM2 is being removed, the cut recess CT_RE may gradually decrease in length in the first direction D1 as the cut recess CT_RE approaches the substrate 100. In an example embodiment, a method for manufacturing the semiconductor device 10 may include forming the gate cut film CT by filling the formed cut recess CT_RE with an insulating material.

According to example embodiments, it is possible to provide a semiconductor device of which integration may be improved by downscaling, and electrical reliability may be improved.

The effect of the example embodiments are not limited to the above-described effects, and other effects not described would be clearly understood by those skilled in the art from the description of the claims.

The example embodiments of the present disclosure are described with reference to the attached drawings. However, the present disclosure is not limited to the example embodiments, and the semiconductor device described in present disclosure can be manufactured in various other forms, and a person skilled in the art to which the present disclosure pertains will understand that the disclosed semiconductor device can be implemented in other specific forms without changing its technical idea or essential features. Therefore, the example embodiments described above should be understood in all respects as illustrative and not limiting.

What is claimed is:

1. A semiconductor device comprising:
a substrate;
a plurality of transistor structures disposed on the substrate and spaced apart from each other in a first direction parallel to a surface of the substrate, each of the plurality of transistor structures comprising a lower portion active pattern and an upper portion active pattern spaced apart from the lower portion active pattern in a second direction intersecting the first direction;
a gate cut film disposed between two adjacent transistor structures of the plurality of transistor structures;
for each lower portion active pattern, a first layer that surrounds at least a first portion of the lower portion active pattern; and
a second layer disposed on each first layer,
wherein each of the plurality of transistor structures comprises a first work-function film surrounding the first portion of the lower portion active pattern and a second work-function film that surrounds at least a first portion of the upper portion active pattern and extends in the first direction, and
wherein the gate cut film penetrates through the second work-function film to form a gap between a first part of the second work-function film and a second part of the second work-function film.

2. The semiconductor device of claim 1, wherein the gate cut film has a length in the first direction that gradually decreases as the gate cut film gets closer to the substrate.

3. The semiconductor device of claim 1, wherein the first work-function film includes a gap formed therein at a location between the plurality of transistor structures.

4. The semiconductor device of claim 1, further comprising a separating insulating film disposed in each transistor structures between the lower portion active pattern and the upper portion active pattern,
wherein the separating insulating film contacts the second work-function film.

5. The semiconductor device of claim 1, wherein at least a common gate transistor structures of the plurality of transistor structures includes a region in which the first work-function film and the second work-function film contact each other.

6. The semiconductor device of claim 5, wherein:
in the common gate transistor structure,
a surface area of an entire contact region where the second work-function film and the second layer contact each other is greater than a surface area of an entire contact region where the first work-function film and the second work-function film contact each other.

7. The semiconductor device of claim 5, wherein:
in the common gate transistor structure,
the second work-function film comprises a bottommost surface in the second direction that is closer to the substrate than an uppermost surface of the first work-function film is to the substrate.

8. The semiconductor device of claim 1, wherein at least a split gate transistor structure of the plurality of transistor structures includes a region in which the first work-function film comprises an uppermost surface in the second direction that is closer to the substrate than a bottommost surface of the second work-function film is to the substrate.

9. The semiconductor device of claim 8, wherein:
in the split gate transistor structure,
a length (T₁) in the second direction between the uppermost surface of the first work-function film and the bottommost surface of the second work-function film is less than 5.8 nm.

10. The semiconductor device of claim 8, wherein the split gate transistor structure further comprises a separating insulating film disposed between the lower portion active pattern and the upper portion active pattern,
a ratio (T₁/T₂) of the length (T₁) between the uppermost surface of the first work-function film and the bottommost surface of the second work-function surface and a length (T₂) of the separating insulating film in the second direction is 0.5 or less.

11. The semiconductor device of claim 1, wherein the first layer comprises a first insulating material and the second layer comprises a second insulating material, and
a portion of the first layer is disposed continuously in the first direction between the plurality of transistor structures.

12. The semiconductor device of claim 11, wherein:
a first transistor structure of the plurality of transistor structures comprises a region in which the first work-function film and the second work-function film contact each other, and
in the first transistor structure, an uppermost surface of the first layer is closer to the substrate than a bottommost surface of the second work-function film is to the substrate.

13. The semiconductor device of claim 11, wherein the plurality of transistor structures comprise a first transistor structure that comprises a region in which the first work-function film and the second work-function film contact each other and a second transistor structure that comprises the first work-function film comprising an uppermost surface that is closer in the second direction to the substrate than a bottommost surface of the second work-function film is to the substrate, and
wherein a maximum thickness in the second direction of the second work-function film of the first transistor structure is the same as a maximum thickness in the second direction of the second work-function film of the second transistor structure.

14. The semiconductor device of claim 1, wherein the first layer comprises a conductive material, and the second layer comprises an insulating material, and
wherein a gap is formed in the first layer between the plurality of transistor structures.

15. The semiconductor device of claim 14, wherein the plurality of transistor structures include a first transistor structure that comprises a region in which the first work-function film and the second work-function film contact each other, and
wherein, in the first transistor structure, the second work-function film comprises a bottommost surface that is closer to the substrate than an uppermost surface of the first layer is to the substrate.

16. The semiconductor device of claim 14, wherein the plurality of transistor structures comprise a first transistor structure that comprises a region in which the first work-function film and the second work-function film contact each other and a second transistor structure that comprises the first work-function film comprising an uppermost surface that is closer in the second direction to the substrate than a bottommost surface of the second work-function film is to the substrate, and
wherein a maximum thickness in the second direction of the second work-function film of the first transistor structure is greater than a maximum thickness in the second direction of the second work-function film of the second transistor structure.

17. The semiconductor device of claim 16, wherein the first transistor structure comprises the first work-function film that comprises a concave portion at an interface with the second work-function film.

18. A semiconductor device comprising:
a substrate;
a plurality of transistor structures disposed on the substrate and spaced apart from each other in a first direction parallel to a surface of the substrate, each comprising a lower portion active pattern comprising a plurality of sheets spaced apart from each other in a second direction intersecting the first direction, an upper portion active pattern spaced apart from the lower portion active pattern in the second direction and comprising a plurality of sheets that are spaced apart from each other in the second direction, and a separating insulating film disposed between the lower portion active pattern and the upper portion active pattern;
a gate cut film disposed between adjacent transistor structures of the plurality of transistor structures;
a first layer that surrounds at least a portion of each of the lower portion active patterns; and
a second layer disposed on the first layer,
wherein the gate cut film penetrates a work-function film in the second direction to fill a gap in the work-function film.

19. The semiconductor device of claim 18, wherein a bottommost surface of the gate cut film is closer to the substrate than an uppermost surface of the separating insulating film is to the substrate.

20. A semiconductor device comprising:
a substrate;
a plurality of transistor structures disposed on the substrate and spaced apart from each other in a first direction parallel to a surface of the substrate, each comprising a lower portion active pattern comprising a plurality of sheets spaced apart from each other in a second direction intersecting the first direction, an upper portion active pattern spaced apart from the lower portion active pattern in the second direction and comprising a plurality of sheets spaced apart from each other in the second direction, and a separating insulating film disposed between the lower portion active pattern and the upper portion active pattern;
a gate cut film disposed between adjacent transistor structures of the plurality of transistor structures;
a first layer that surrounds at least a portion of each of the lower portion active patterns; and
a second layer disposed on the first layer,
wherein the gate cut film penetrates a second work-function film in the second direction in order for the second work-function film to have a gap therein with respect to the first direction, and a length of the gate cut film with respect to the first direction decreases as the gate cut film gets closer to the substrate,
wherein the gate cut film comprises a bottommost surface that is closer to the substrate than an uppermost surface of the separating insulating film is to the substrate,
wherein a portion of a first work-function film has a gap formed therein between the plurality of transistor structures, and
wherein the separating insulating film contacts the second work-function film.
